(19) United States
(12) Patent Application Publication
(10) Pub. No.: US 2025/0132749 A1
(43) Pub. Date: Apr. 24, 2025

(54) WIDEBAND ELECTRONICALLY TUNABLE FILTER AND METHOD

(71) Applicant: Nanowave Technologies Inc., Etobicoke (CA)

(72) Inventors: Charles William Tremlett NICHOLLS, Nepean (CA); Walid HAMDANE, Tunis (TN)

(21) Appl. No.: 18/832,958

(22) PCT Filed: Feb. 7, 2023
(86) PCT No.: PCT/CA2023/050153

§ 371 Date: Jul. 25, 2024

Related U.S. Application Data
(60) Provisional application No. 63/307,834, filed on Feb. 8, 2022.

(51) Int. Cl. H03H 11/04; H04B 1/00

(52) U.S. Cl. CPC H03H 11/04; H04B 1/006

(57) ABSTRACT

In an aspect herein, the disclosure provides a method for implementing a wideband electronically tunable filter, comprising: receiving an RF input at a first frequency within a first RF band; up-converting the RF input based on mixing the RF input with a transposition signal from a second RF band non-overlapping with the first RF band; generating an RF filter output based on applying an RF filter characteristic to the up-converted RF input; down-converting the RF filter output based on mixing the RF filter output with the transposition signal, and outputting an RF output based on the down-converted RF filter output.

### FIELD

The present disclosure relates generally to radio frequency systems, and more particularly to electronically tunable filters (ETF), and even more particularly to wideband ETFs.

### BACKGROUND

Radio systems generally operate over specific frequency bands and thus generally require means to limit the operational bandwidth of the system in both the transmission and reception modes. Two broad categories of radio frequency systems include Radio Detection And Ranging (RADAR) and telecommunications systems.

It remains desirable however to develop further improvements and advancements in relation to radio frequency systems, including in relation to RADAR and telecommunications systems, to overcome shortcomings of known techniques, and to provide additional advantages thereto.

This section is intended to introduce various aspects of the art, which may be associated with the present disclosure. This discussion is believed to assist in providing a framework to facilitate a better understanding of particular aspects of the present disclosure. Accordingly, it should be understood that this section should be read in this light, and not necessarily as admissions of prior art.

### BRIEF DESCRIPTION OF THE DRAWINGS

Embodiments of the present disclosure will now be described, by way of example only, with reference to the attached Figures.

FIGS. 1A and 1B are each a block diagram of an embodiment of a serially cascaded electronically tunable filter having a switched filter bank at each of the input end and output end of the filter.

FIG. 2 is a plot illustrating the sideband outputs of an up-conversion mixer according to FIG. 1.

FIG. 3 is a flow chart of a method embodiment for implementing a wideband electronically tunable filter at RF in accordance with the present disclosure.

FIG. 4 is a block diagram of an embodiment of a transposition network in accordance with the present disclosure, for use in transposing an RF input to a desired frequency.

FIG. 5A is a schematic diagram of a wideband electronically tunable filter in accordance with the present disclosure wherein operational bandwidths of the ETF and local oscillator are non-overlapping.

FIG. 5B is a schematic diagram of a wideband electronically tunable filter having a delay element in accordance with the present disclosure wherein operational bandwidths of the ETF and local oscillator are non-overlapping.

FIG. 6 is a plot illustrating the sideband outputs of a down-conversion mixer according to FIG. 5A.

FIG. 7 is a plot of a simulated passband filter characteristic for a 9th order Chebyshev filter implemented at RF in a wideband electronically tunable filter in accordance with the present disclosure.

FIG. 8 illustrates two plots corresponding to simulated passband characteristics transposed down from RF and respectively centered at 9980 MHz and 14030 MHz in accordance with embodiments of a wideband electronically tunable filter as disclosed herein.

FIG. 9 is a block diagram of a wideband electronically tunable filter comprising two serially connected electronically tunable filters in accordance with the present disclosure, wherein the two filters provide an adjustable overlapping passband based on a relative offset between the two filters.

FIG. 10 is a schematic diagram of a wideband electronically tunable filter comprising two serially connected electronically tunable filters in accordance with the present disclosure, wherein the two filters provide an adjustable overlapping passband based on a relative offset between the two filters.

FIG. 11 is a plot of an adjustable passband characteristic based on adjusting a relative offset between two adjustable filter characteristics in accordance with an embodiment of the present disclosure.

FIG. 12 is a plot of a simulated adjustable passband derived from offsetting two instances of a filter characteristic in accordance with an embodiment of the present disclosure.

FIG. 13 is a plot of simulating adjusting a center frequency across an operational bandwidth of 1 to 20 GHz of an idealized 10 pole elliptic filter, having a 2 GHz pass band, implemented in a wideband electronically tunable filter in accordance with the present disclosure.

FIG. 14 is a plot of simulating an idealized 10 pole elliptic filter implemented in a wideband electronically tunable filter in accordance with the present disclosure, where the elliptic filter bandwidth is increased in steps of 500 MHz intervals from 500 MHz to 2 GHz extending the operational bandwidth from 9500 MHz to 10000 MHz; to, 9500 MHz to 11500 MHz.

FIG. 15 is an enlarged view of a plot captured in a viewing area of FIG. 14 showing a 10 MHz passband.

FIG. 16 is a block diagram of a wideband electronically tunable filter comprising two electronically tunable filters connected in parallel in accordance with the present disclosure, wherein the two filters provide an adjustable bandwidth stopband notch or an increased passband bandwidth based on a relative offset between the two filters.

FIG. 17 is a schematic diagram of a wideband electronically tunable filter comprising two electronically tunable filters connected in parallel in accordance with the present disclosure, wherein the two filters provide an adjustable bandwidth stopband notch or an increased passband bandwidth based on a relative offset between the two filters.

FIG. 18 is a plot of a simulated passband characteristic for a wideband electronically tunable filter having a first and second ETF configured in parallel in accordance with the present disclosure. The plot includes first and second passband characteristics based on different relative center frequency offsets between first and second transposed filter characteristics resulting in an adjustable bandwidth notch filter in accordance with an embodiment of the present disclosure.

FIG. 19 is a plot of simulated passband characteristics for a wideband electronically tunable filter having a first and second ETF configured in parallel in accordance with the present disclosure, such as the wideband filters 1600 and 1700 illustrated in FIGS. 16 and 17, respectively. The plot overlays various passband characteristics and their corresponding stopbands based on correspondingly shifting two transposed filter characteristics across an operational bandwidth of the wideband electronically tunable filter.

FIG. 20 is a plot of a simulated passband characteristic for a wideband electronically tunable filter having a first and second ETF configured in parallel in accordance with the present disclosure. The plot demonstrates adjusting the bandwidth of a stopband within the passband characteristic based on adjusting the relative center frequency offset between two transposed filter characteristics.

FIG. 21 is a plot of a simulated passband characteristic for a wideband electronically tunable filter having a first and second ETF configured in parallel in accordance with the present disclosure. The passband characteristic is based on the overlapping superposition of a first and second transposed filter resulting in increased operational bandwidth for the wideband electronically tunable filter.

FIG. 22 is a block diagram of a wideband electronically tunable filter comprising a parallel configuration of respective first and second electronically tunable filters each comprising two serially cascaded ETFs in accordance with an embodiment of the present disclosure.

FIG. 23 is a flow chart of a method embodiment for implementing a wideband electronically tunable filter having a nested electronically tunable filter implemented at IF in accordance with the present disclosure.

FIG. 24 is a schematic diagram of a wideband electronically tunable filter comprising a first transposition to RF to improve spurious performance and a second transposition to IF to implement a nested electronically tunable filter at IF.

FIG. 25 illustrates four plots corresponding to simulated passband characteristics transposed up from IF and respectively centered at 1020 MHz, 9000 MHz, 11020 MHz, and 16000 MHz in accordance with embodiments of a wideband electronically tunable filter having a nested electronically tunable filter implemented at IF as disclosed herein.

FIG. 26 is a schematic diagram of a wideband electronically tunable filter comprising a first transposition to RF to improve spurious performance and a second transposition to IF to implement two serially cascaded electronically tunable filters nested at IF.

FIG. 27 plots three simulated adjustable passbands derived from cascading two electronically tunable filters nested in series at IF in accordance with an embodiment of the present disclosure.

FIG. 28 is a plot of simulating adjusting a center frequency across a bandwidth of 9915 MHz to 10067 MHz for a wideband electronically tunable filter having a narrow passband characteristic nested at IF in accordance with an embodiment of the present disclosure.

FIG. 29 is a block diagram of an example computing device or system for implementing a wideband electronically tunable filter and method in accordance with the present disclosure.

Throughout the drawings, sometimes only one or fewer than all of the instances of an element visible in the view are designated by a lead line and reference character, for the sake only of simplicity and to avoid clutter. It will be understood, however, that in such cases, in accordance with the corresponding description, that all other instances are likewise designated and encompasses by the corresponding description.

### DETAILED DESCRIPTION

The following are examples of systems and methods of a wideband electronically tunable filter in accordance with the present disclosure.

In an aspect herein, the disclosure provides an electronically tunable filter, comprising: a signal generator for generating a transposition signal; an input mixer in communication with the signal generator and configured to receive the transposition signal and a radio frequency (RF) input at a first frequency within an first RF band, the input mixer configured to output an up-converted RF input based on mixing the RF input with the transposition signal; a filter in communication with the input mixer and configured to receive the up-converted RF input, the filter producing a filter output based on applying a filter characteristic to the up-converted RF input, wherein the filter is selected to have a passband for limiting operation of the signal generator to a second RF band non-overlapping with the first RF band, for transposing the RF input to within the passband of the filter, and an output mixer in communication with the filter and the signal generator and configured to receive the filter output and the transposition signal, the output mixer configured to produce an RF output based on down-converting the filter output to the first frequency based on mixing with the transposition signal.

In an example embodiment disclosed herein, the input mixer and the output mixer comprise an image rejection mixer or a double balance mixer.

In an example embodiment disclosed herein, the filter is an RF filter comprising a cavity filter, a waveguide filter, a microstrip filter, and an integrated monolithic microwave integrate circuit filter.

In an example embodiment disclosed herein, the filter comprises a bandpass filter having a filter bandwidth centered about a center frequency of the filter.

In an example embodiment disclosed herein, the bandpass filter comprises a cavity-based bandpass filter, wherein the center frequency is 44 GHz and the filter bandwidth is 2 GHz.

In an example embodiment disclosed herein, the first RF band is about 1 GHz to about 20 GHz and the second RF band is about 24 GHz to about 43 GHz.

In an example embodiment disclosed herein, a separation bandwidth between an upper limit of the first RF band and a lower limit of the second RF band is at least 1 GHz.

In an example embodiment disclosed herein, a separation bandwidth between an upper limit of the first RF band and a lower limit of the second RF band is at least 500 MHz.

In an example embodiment disclosed herein, the electronically tunable filter further comprises: a first filter having a first low pass filter characteristic based on a first cutoff frequency, the first low pass filter being configured to receive the RF input and apply the first low pass filter characteristic, wherein the input mixer receives the RF input from an output of the first low pass filter.

In an example embodiment disclosed herein, the first cutoff frequency is 20 GHz.

In an example embodiment disclosed herein, the electronically tunable filter further comprises: a second filter having a second low pass filter characteristic based on a second cutoff frequency, the second low pass filter being in communication with the output mixer and configured to apply the second low pass filter characteristic to the RF output.

In an example embodiment disclosed herein, the second cutoff frequency is 20 GHz.

In an aspect herein, the disclosure provides a cascaded filter, comprising: a first electronically tunable filter according to the disclosure herein, connected in series with, a second electronically tunable filter according to the disclosure herein; wherein the RF output of the first electronically tunable filter is provided as the RF input of the second electronically tunable filter.

In an example embodiment disclosed herein, the passband of the filter of the first electronically tunable filter is offset relative to the passband of the filter of the second electronically tunable filter.

In an example embodiment disclosed herein, an output of the cascaded filter is based on an overlap between the passband of the filter of the first electronically tunable filter and the passband of the filter of the second electronically tunable filter.

In an aspect herein, the disclosure provides a notch filter, comprising: a plurality of electronically tunable filters, according to the disclosure herein, connected in parallel; wherein a notch filter output comprises the RF output of each of the plurality of electronically tunable filters.

In an example embodiment disclosed herein, the plurality of electronically tunable filters comprises a first electronically tunable filter and a second electronically tunable filter; wherein the notch filter output comprises the RF output of the first electronically tunable filter and the RF output of the second electronically tunable filter.

In an example embodiment disclosed herein, the notch filter further comprises: a first low pass filter having a first low pass filter characteristic based on a first cutoff frequency, the first low pass filter being configured to receive the RF input and apply the first low pass filter characteristic, wherein the input mixer of each of the first and second electronically tunable filter receives the RF input from an output of the first low pass filter.

In an example embodiment disclosed herein, the first cutoff frequency is 20 GHz.

In an example embodiment disclosed herein, the notch filter further comprises: a second low pass filter having a second low pass filter characteristic based on a second cutoff frequency, the second low pass filter configured to apply the second low pass filter characteristic to the notch filter output wherein the notch filter output comprises an output of the second low pass filter.

In an example embodiment disclosed herein, the second cutoff frequency is 20 GHz.

In an example embodiment disclosed herein, the passband of the filter of the first electronically tunable filter is offset relative to the passband of the filter of the second electronically tunable filter.

In an example embodiment disclosed herein, the notch filter further comprises: a stopband between the passband of the first electronically tunable filter and the passband of the second electronically tunable filter, the stopband based on the relative offset between the passbands.

In an aspect herein, the disclosure provides a nested electronically tunable filter (NETF), comprising: an input transposition network configured to provide a first RF output comprising an RF input transposed up to a RF transposition frequency, the first RF output based on applying a first RF filter characteristic to an output of an up-conversion mixer configured to mix the RF input with a first transposition signal, wherein a passband of the first RF filter characteristic limits selection of the first transposition signal to a second RF band non-overlapping with a first RF band comprising the RF input; an electronically tunable filter (ETF), comprising: a signal generator for generating a second transposition signal; an input mixer configured to provide an intermediate frequency (IF) output comprising the first RF output transposed down to an IF transposition frequency of an IF band, the IF output based on mixing the first RF output with the second transposition signal; an IF filter in communication with the input mixer and configured to provide an IF filter output based on applying an IF filter characteristic to the IF output, and an output mixer configured to provide a second RF output comprising the IF filter output transposed up to the RF transposition frequency, the second RF output based on mixing the IF filter output with the second transposition signal, and an output transposition network configured to provide a third RF output comprising a second RF filter output transposed down to the first RF band, the third RF output based on an output of a down-conversion mixer configured to mix the second RF filter output with the first transposition signal, wherein the second RF filter output is based on applying a second RF filter characteristic to the second RF output.

In an example embodiment disclosed herein, the up-conversion mixer, the input mixer, the output mixer, and the down-conversion mixer each comprise either a image rejection mixer or a double balance mixer.

In an example embodiment disclosed herein, the IF filter comprises a surface acoustic wave (SAW) filter, a multi-pole ceramic resonator filter, a microstrip filter, or a crystal filter.

In an example embodiment disclosed herein, the IF filter comprises a bandpass filter having a filter bandwidth centered about a center frequency of the filter.

In an example embodiment disclosed herein, the bandpass filter comprises a SAW-based bandpass filter, wherein the center frequency is about 950 MHz and the filter bandwidth is about 150 MHz.

In an example embodiment disclosed herein, the first RF band is about 1 GHz to about 20 GHz and the second RF band is about 21 GHz to about 40 GHz.

In an example embodiment disclosed herein, a separation bandwidth between an upper limit of the first RF band and a lower limit of the second RF band is at least 1 GHz.

In an example embodiment disclosed herein, a separation bandwidth between an upper limit of the first RF band and a lower limit of the second RF band is at least 500 MHz.

In an example embodiment disclosed herein, the NETF further comprises: a first filter having a first low pass filter characteristic based on a first cutoff frequency, the first low pass filter being configured to receive the RF input and apply the first low pass filter characteristic, wherein the up-conversion mixer receives the RF input from an output of the first low pass filter.

In an example embodiment disclosed herein, the first cutoff frequency is 20 GHz.

In an example embodiment disclosed herein, the NETF further comprises: a second filter having a second low pass filter characteristic based on a second cutoff frequency, the second low pass filter being in communication with the down-conversion mixer and configured to apply the second low pass filter characteristic to the third RF output.

In an example embodiment disclosed herein, the second cutoff frequency is 20 GHz.

In an aspect herein, the disclosure provides a nested electronically tunable filter, comprising: an input transposition network configured to provide a first RF output comprising an RF input transposed up to a RF transposition frequency, the first RF output based on applying a first RF filter characteristic to an output of an up-conversion mixer configured to mix the RF input with a first transposition signal, wherein a passband of the first RF filter characteristic limits selection of the first transposition signal to a second RF band non-overlapping with a first RF band comprising the RF input; a first electronically tunable filter connected in series with a second electronically tunable filter, each of the first ETF and the second ETF comprising: a signal generator for generating a second transposition signal; an input mixer configured to provide an intermediate frequency (IF) output comprising the first RF output transposed down to an IF transposition frequency of an IF band, the IF output based on mixing the first RF output with the second transposition signal; an IF filter in communication with the input mixer and configured to provide an IF filter output based on applying an IF filter characteristic to the IF output, and an output mixer configured to provide a second RF output comprising the IF filter output transposed up to the RF transposition frequency, the second RF output based on mixing the IF filter output with the second transposition signal; wherein the first RF input of the second ETF comprises the second RF output of the first ETF, and an output transposition network configured to provide a third RF output comprising a second RF filter output transposed down to the first RF band, the third RF output based on an output of a down-conversion mixer configured to mix the second RF filter output with the first transposition signal, wherein the second RF filter output is based on applying a second RF filter characteristic to the second RF output.

In an example embodiment disclosed herein, a passband of the IF filter characteristic of the first ETF is offset relative to a passband of the IF filter characteristic of the second ETF.

In an example embodiment disclosed herein, an output of the NETF is based on an overlap between the passband of the IF filter of the first ETF and the passband of the IF filter of the second ETF.

In aspect herein, the disclosure provides a method for implementing a wideband electronically tunable filter, comprising: receiving an RF input at a first frequency within a first RF band; up-converting the RF input based on mixing the RF input with a transposition signal from a second RF band non-overlapping with the first RF band; generating an RF filter output based on applying an RF filter characteristic to the up-converted RF input; down-converting the RF filter output based on mixing the RF filter output with the transposition signal, and outputting an RF output based on the down-converted RF filter output.

In an example embodiment disclosed herein, the up-converting and down-converting based on mixing comprises use of either an image rejection mixer or a double balance mixer.

In an example embodiment disclosed herein, the generating the RF filter output comprises use of an RF filter selected from the group consisting of a cavity filter, a waveguide filter, a microstrip filter, and an integrated monolithic microwave integrate circuit filter.

In an example embodiment disclosed herein, the RF filter characteristic comprises a bandpass filter characteristic having a center frequency and a filter bandwidth.

In an example embodiment disclosed herein, the center frequency is about 44 GHz and the filter bandwidth is about 2 GHz.

In an example embodiment disclosed herein, the first RF is about 1 GHz to about 20 GHz and the second RF band is about 24 GHz to about 43 GHz.

In an example embodiment disclosed herein, a separation bandwidth between an upper limit of the first RF band and a lower limit of the second RF band is at least 1 GHz.

In an example embodiment disclosed herein, a separation bandwidth between an upper limit of the first RF band and a lower limit of the second RF band is at least 500 MHz.

In an example embodiment disclosed herein, the method further comprises: applying a first low pass filter characteristic to the RF input, the first low pass filter characteristic having a first cutoff frequency.

In an example embodiment disclosed herein, the first cutoff frequency is 20 GHz.

In an example embodiment disclosed herein, the method further comprises: applying a second low pass filter characteristic to the RF output, the second low pass filter characteristic having a second cutoff frequency.

In an example embodiment disclosed herein, the second cutoff frequency is 20 GHz.

In an aspect herein, the disclosure provides a method for implementing a cascaded filtering, comprising: implementing a first electronically tunable filter in series with, a second electronically tunable filter according to an embodiment of the present disclosure; wherein the RF output of the first electronically tunable filter is provided as the RF input of the second electronically tunable filter.

In an example embodiment disclosed herein, the method further comprises: applying the RF filter characteristic of the first electronically tunable filter at a first RF center frequency, and applying the RF filter characteristic of the second electronically tunable filter at a second RF center frequency; wherein the first RF center frequency and the second RF center frequency are relatively offset.

In an example embodiment disclosed herein, an output of the cascaded filter is based on an overlapping passband between the RF filter characteristic of the first electronically tunable filter and the RF filter characteristic of the second electronically tunable filter.

In an aspect herein, the disclosure provides a method for implementing a notch filter, comprising: implementing a plurality of electronically tunable filters according to an embodiment disclosed herein, each of the plurality of the plurality of electronically tunable filters being connected in parallel, and outputting a notch filter output comprising the RF output of each of the plurality of electronically tunable filters.

In an aspect herein, the disclosure provides a method for implementing a notch filter, comprising: implementing a first electronically tunable filter in parallel with a second electronically tunable filter according to an embodiment of the present disclosure; outputting a notch filter output comprising the RF output of the first electronically tunable filter and the RF output of the second electronically tunable filter.

In an example embodiment disclosed herein, the method further comprises: applying a first low pass filter characteristic to the RF input, the first low pass filter characteristic having a first cutoff frequency.

In an example embodiment disclosed herein, the first cutoff frequency is 20 GHz.

In an example embodiment disclosed herein, the method further comprises: applying a second low pass filter characteristic to the notch filter output, the second low pass filter characteristic having a second cutoff frequency.

In an example embodiment disclosed herein, the second cutoff frequency is 20 GHz.

In an example embodiment disclosed herein, the method further comprises: applying the RF filter characteristic of the first electronically tunable filter at a first RF center frequency, and applying the RF filter characteristic of the second electronically tunable filter at a second RF center frequency; wherein the first RF center frequency and the second RF center frequency are relatively offset.

In an example embodiment disclosed herein, the method further comprises: controlling a bandwidth of a stopband based on adjusting a relative offset between the first RF center frequency and the second RF center frequency.

An aspect herein, the disclosure provides a method for implementing a nested electronically tunable filter at an intermediate frequency (IF), comprising: receiving an RF input at a first frequency within an first RF band; up-converting the RF input based on mixing the RF input with a transposition signal from a second RF band non-overlapping with the first RF band; generating an RF filter output based on applying an RF filter characteristic to the up-converted RF input; down-converting the RF filter output to an IF band based on mixing the RF filter output with a second transposition signal; generating an IF filter output based on applying an IF filter characteristic to the down-converted RF filter output; up-converting the IF filter output based on mixing the RF filter output with the second transposition signal; generating a second RF filter output based on applying a second RF filter characteristic to the up-converted IF filter output; down-converting the second RF filter output based on mixing the second RF filter output with the transposition signal, and outputting an RF output based on the down-converted RF filter output.

In an example embodiment disclosed herein, all steps of mixing comprise use of either a image rejection mixer or a double balance mixer.

In an example embodiment disclosed herein, the IF filter comprises a surface acoustic wave (SAW) filter, a multi-pole ceramic resonator filter, a microstrip filter, or a crystal filter.

In an example embodiment disclosed herein, the IF filter comprises a bandpass filter having a filter bandwidth centered about a center frequency.

In an example embodiment disclosed herein, the bandpass filter comprises a SAW-based bandpass filter, wherein the filter bandwidth is about 150 MHz and the center frequency is about 950 MHz.

In an example embodiment disclosed herein, the first RF band comprises 1 GHz to 20 GHz and the second RF band comprises 21 GHz to 40 GHz.

In an example embodiment disclosed herein, a separation bandwidth between an upper limit of the first RF band and a lower limit of the second RF band is at least 1 GHz.

In an example embodiment disclosed herein, a separation bandwidth between an upper limit of the first RF band and a lower limit of the second RF band is at least 500 MHz.

In an example embodiment disclosed herein, the method further comprises: applying a first low pass filter characteristic to the RF input, the first low pass filter characteristic having a first cutoff frequency.

In an example embodiment disclosed herein, the first cutoff frequency is 20 GHz.

In an example embodiment disclosed herein, the method further comprises: applying a second low pass filter characteristic to the RF output, the second low pass filter characteristic having a second cutoff frequency.

In an example embodiment disclosed herein, the second cutoff frequency is 20 GHz.

In an aspect herein, the disclosure provides a method for implementing serially cascaded electronically tunable filters, nested at an intermediate frequency (IF), comprising: receiving an RF input at a first frequency within an first RF band; up-converting the RF input based on mixing the RF input with a transposition signal from a second RF band non-overlapping with the first RF band; generating an RF filter output based on applying an RF filter characteristic to the up-converted RF input; down-converting the RF filter output to an IF band based on mixing the RF filter output with a second transposition signal; generating an IF filter output based on applying an IF filter characteristic to the down-converted RF filter output; up-converting the IF filter output based on mixing the RF filter output with the second transposition signal; down-converting the up-converted IF filter output based on mixing the up-converted IF filter output with a third transposition signal; generating a second IF filter output based on applying a second IF filter characteristic to the down-converted IF filter output; up-converting the second IF filter output based on mixing the second IF filter output with the third transposition signal; generating a second RF filter output based on applying a second RF filter characteristic to the up-converted second IF filter output; down-converting the second RF filter output based on mixing the second RF filter output with the transposition signal, and outputting an RF output based on the down-converted RF filter output.

In an example embodiment disclosed herein, the method further comprises: applying the IF filter characteristic at a first IF center frequency, and applying the second IF filter characteristic at a second RF center frequency; wherein the first IF center frequency and the second IF center frequency are relatively offset.

In an example embodiment disclosed herein, the RF output is based on an overlapping passband between the IF filter characteristic and the second IF filter characteristic.

In an aspect herein, the disclosure provides a computer-readable medium having instructions stored thereon that when executed by a processor perform a method for implementing a filter in accordance with an embodiment disclosed herein.

Electronically tunable filters may suffer from signal degradation arising from frequency mixing required to transpose input RF frequencies to IF. In particular, wideband operation of an electronically tunable filter may cause the operational bandwidth of the electronically tunable filter to overlap with the operating bandwidth of the signal generator used to control frequency transposition. Consequently, signal generator spurs may fall within an operational bandwidth of the wideband electronically tunable filter, thereby contaminating the system output with unwanted spurs and degrading system performance.

In an aspect, a wideband electronically tunable filter is provided at IF and coupled with switched filter banks at an input and output of the system, to provide sub-banding of the system inputs and outputs for selectively suppressing signal generator spurs.

In an aspect, a wideband electronically tunable filter is provided at RF in a manner which causes the operating range of the signal generator to not overlap with the operational bandwidth of the wideband electronically tunable filter, thereby causing signal generator spurs to fall outside the operational bandwidth of the system. Advantageously, operating in non-overlapping bands eliminates the need to filter signal generator spurs through the use of switched filter banks, resulting in power consumption improvements, smaller form factor and weight, reduced design complexity, and lower spurious levels.

In an aspect, a wideband electronically tunable filter is provided, implementing aspects of an ETF at both RF and IF. For example, a first transposition to RF is provided to implement non-overlapping operation of the system and signal generator, thereby enabling improved spurious performance; and, a second transposition to IF is provided to enable use of higher Q factor IF filters, or other IF filters with improved filter characteristics, such as narrower passbands and sharper roll-off characteristics.

Other aspects of a wideband electronically tunable filter may include cascading a plurality of electronically tunable filters in series to provide an adjustable narrow passband; and/or, implementing a plurality of electronically tunable filters in parallel, to provide an adjustable passband with increased bandwidth and/or stopbands or notches.

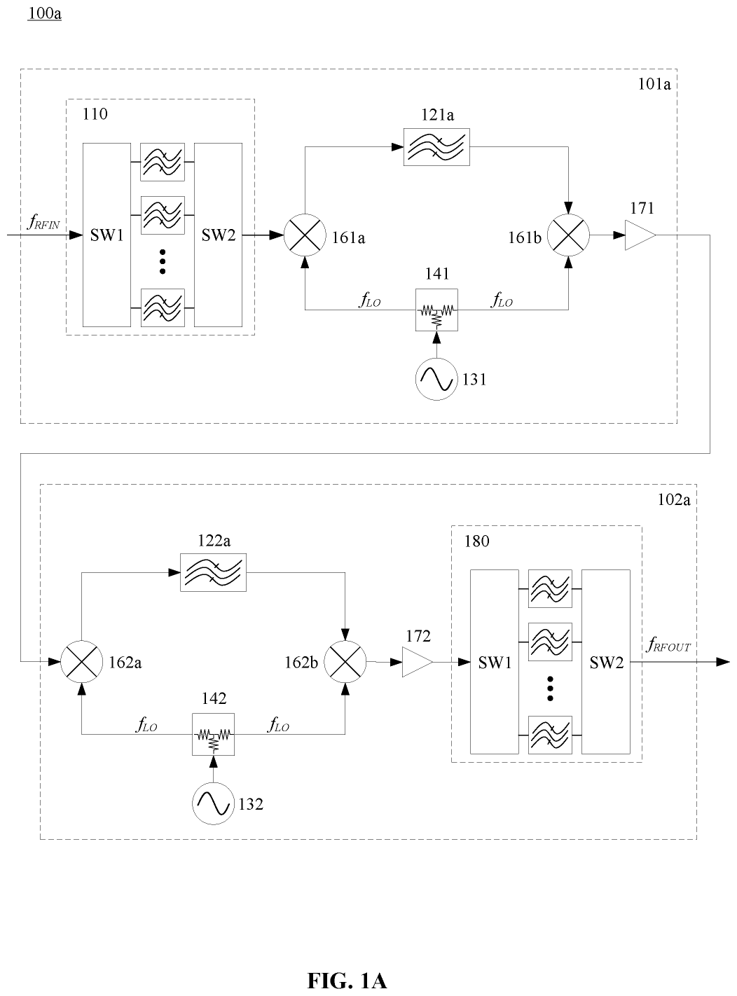

FIGS. 1A and 1B illustrate a diagram of an electronically tunable filter 100a and 100b, respectively, each comprising a first electronically tunable filter 101a and 101b, respectively, cascaded in series with a second electronically tunable filter 102a and 102b, respectively. In an embodiment each of the electronically tunable filters 100a and 100b comprise an adjustable filter center frequency between 1 and 20 GHz.

The first and second electronically tunable filters 101a and 102a of the electronically tunable filter 100a, illustrated in FIG. 1A, each comprise an intermediate frequency (IF) passband filter 121a and 122a, respectively, connected in series between a pair of mixers. In particular, the IF filter 121a is connected between a down-conversion mixer 161a and up-conversion mixer 161b; and, the IF filter 122a is connected between a down-conversion mixer 162a and up-conversion mixer 162b. In this embodiment, filter transposition is achieved by first down converting an RF input to the IF filter passband followed by up converting the filtered IF signal back to the original RF operating frequency based on mixing with a transposition signal f_{LO} generated by a signal generator 131 and 132, which is routed to the pairs of mixers via a power splitter 141 and 142; wherein the IF passband filters 121a and 122a provides a transfer function at a lower IF frequency for subsequent transposition to a higher RF frequency. However, where the electronically tunable filter 100a operates over a frequency range which includes the transposition signal, rejection of the transposition signal may be limited to the transposition mixers which are often insufficient for addressing spurious requirements. For example, the electronically tunable filter 100a may have an operating bandwidth of 1-20 GHz and the signal generators 131 and 132 may have an operating bandwidth of 2-21 GHz for transposing an RF input f_{RFIN} to a 150 MHz passband of the IF filters 121a and 122a, centered at 1 GHz. Consequently, mixing the RF input with the transposition signal may introduce unwanted local oscillator spurs which can propagate through to the system output, f_{RFOUT}.

One solution to suppressing local oscillator spurs while also maintaining a wideband input is the use of switched filter banks, in particular an input switched filter bank 110 and an output switched filter bank 180. The switched filter banks 110 and 180 function to selectively limit the effective bandwidth of the filter 100 to a sub-band of the filter bank. However, a switched filter bank introduces additional size, weight, power consumption, and design complexity for the electronically tunable filters 100a and 100b. For example, implementing an electronically tunable filter with an operational bandwidth of 20 GHz with an IF filter centered at 1 GHz may require 11 or more sub banded switch filters per switched filter bank. Furthermore, band select filter switching requires synchronization to ensure switched filter banks provide passband operation over the correct operational RF band. Further yet, as illustrated in FIG. 1B, to address the special case of the RF input frequency equalling the IF frequency, an additional IF filter may be required along with appropriate RF selection switches, introducing further cost, size, weight, power consumption, and complexity to the design of the filter 100. To implement this requirement, for example, the first electronically tunable filter 101b replaces the single IF filter 121a illustrated in FIG. 1A with a switched filter bank 121b comprising two IF filters; similarly, the second electronically tunable filter 102b replaces the single IF filter 122a illustrated in FIG. 1A with a switched filter bank 122b comprising two IF filters.

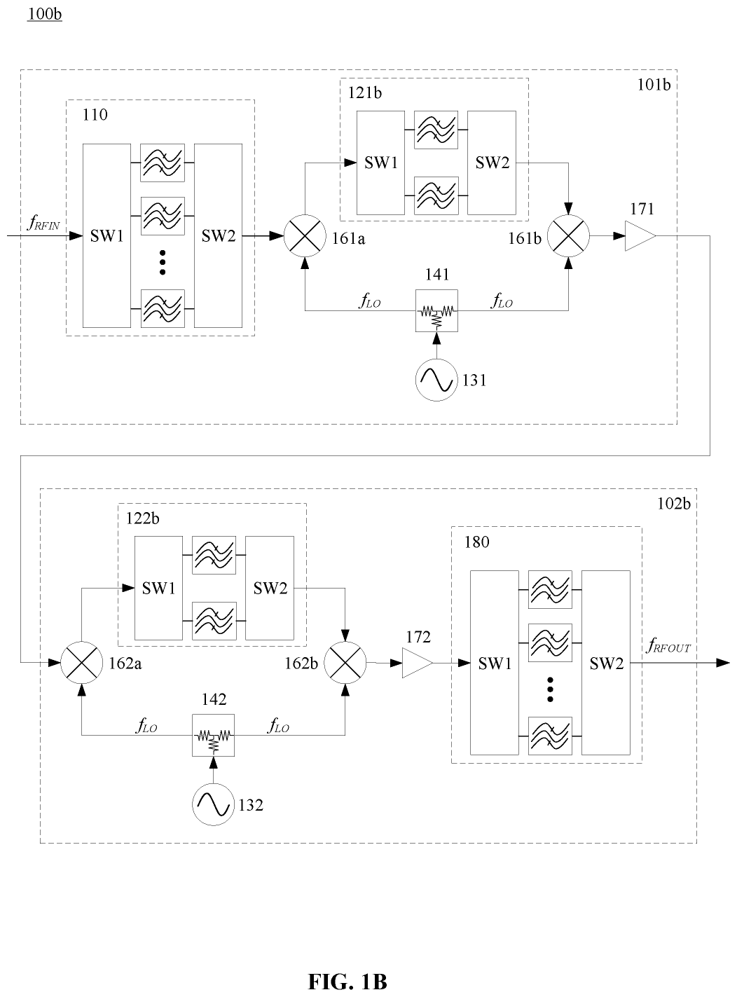

FIG. 2 illustrates a plot of the output from an up-conversion mixer depicted in FIG. 1 which includes the filtered IF signal and the transposition signal. In particular, FIG. 2 illustrates the transposition signal F_{LO}, a lower sideband output 220, and an upper sideband output 230. The sideband outputs are offset from the transposition signal by an amount equal to the center frequency F_{c} of the IF filter. Consequently, increasing the center frequency F_{c} of the IF filter also increases the separation between the upper and lower sideband outputs of the up-conversion mixer. Though the upper sideband output 230 may meet spurious requirements for the system, the lower sideband output 220 may not meet such spurious requirements, necessitating suppression of the lower sideband output 220. One solution to suppressing the lower sideband output 220 and the transposition signal is to implement a plurality of fixed frequency roofing filters 210 which selectively provide passbands spanning the operational bandwidth of the filter 100, for selectively suppressing unwanted signals. For example, selectively applying the roofing filter 212 allows the upper sideband output 230 to pass whilst simultaneously supressing the transposition signal F_{LO} and the lower sideband output 220.

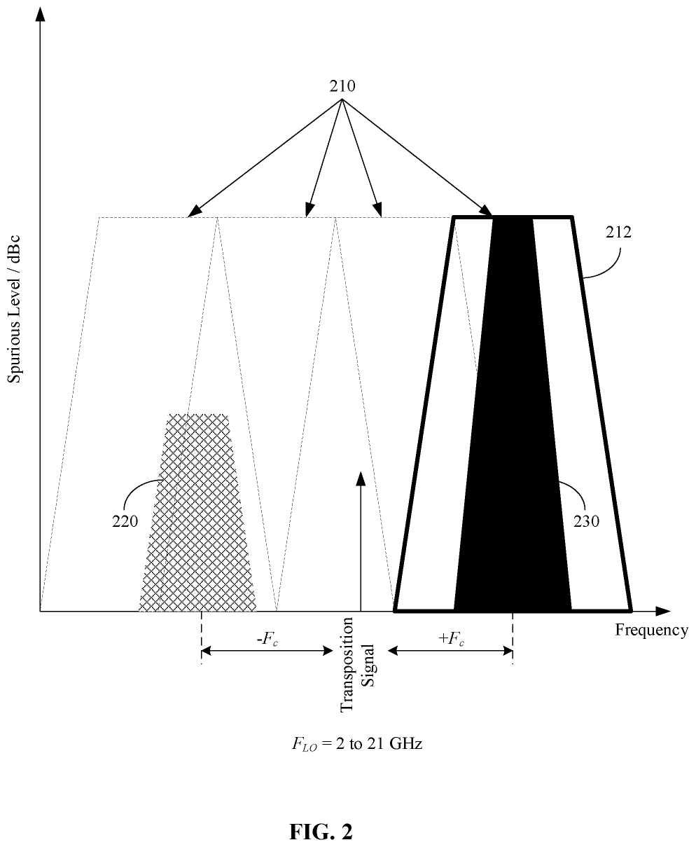

FIG. 3 illustrates a method 300 for implementing a wideband electronically tunable filter at RF in accordance with an embodiment of the present disclosure. The operation of the method 300 is not intended to be limiting but rather illustrates an example of a wideband electronically tunable filter at RF. In some embodiments, the method 300 may be accomplished with one or more additional operations not described, and/or without one or more of the operations described. Similarly, the order in which the operation of method 300 is illustrated and described below is not intended to be limiting, but rather illustrative of an example of implementing a wideband electronically tunable filter at RF in accordance with the present disclosure.

In some embodiments, the method 300 may be implemented in one or more processing devices (e.g., a digital processor, an analog processor, a digital circuit designed to process information, an analog circuit designed to process information, a computing network implemented in the cloud, a state machine, and/or other mechanisms for electronically processing information). The one or more processing devices may include one or more devices executing some or all of the operations of the method 300 in response to instructions stored electronically on an electronic storage medium. The one or more processing devices may include one or more devices configured through hardware, firmware, and/or software to be specifically designed for execution of one or more of the operations of the method 300.

The method 300 may include an operation 310 for receiving an RF input at a first RF frequency within an operating bandwidth of the electronically tunable filter. In an embodiment, the operational bandwidth of the wideband electronically tunable filter is set by low pass-filters at an input and an output of the electronically tunable filters. In an embodiment, the operational bandwidth is 1-20 GHz.

The method 300 may include an operation 320 for up-converting the RF input to a passband of an RF filter based on mixing the RF input with a transposition signal generated by a signal generator, such as generated by a local oscillator. The RF filter is selected to have a passband which limits the signal generator to operate in an RF band outside of the operational bandwidth of the electronically tunable filter, advantageously causing signal generator spurs to similarly fall outside the operational bandwidth of the electronically tunable filter. In an embodiment, the RF filter is selected to have a 2 GHz passband centered at 44 GHz. In an embodiment, the electronically tunable filter operational bandwidth is 1-20 GHz, the RF filter is selected to have a 2 GHz passband centered at 44 GHz, and the signal generator is limited to operate from 24-43 GHz in order to transpose an RF input to a passband of the RF filter.

The method 300 may include an operation 330 for applying an RF filter characteristic of an RF filter to the up-converted RF input. In an embodiment, the RF filter comprises a bandpass filter. In an embodiment, the RF filter may comprise a cavity filter, a waveguide filter, a microstrip filter, an integrated Monolithic Microwave Integrated Circuit (MMIC) filter, or combinations thereof. For example, depending on bandwidth and transition band requirements, the RF filter may comprise a MMIC filter, providing smaller form factor relative to other RF filters.

The method 300 may include an operation 340 for down-converting the RF filter output to the first RF frequency based on mixing the RF filter output with a transposition signal.

The method 300 may include an operation 350 for applying an output filter to the down-converted RF filter output, for suppressing oscillator spurs falling outside the operational bandwidth of the electronically tunable filter. In an embodiment, the output filter is a low pass filter. In an embodiment, the output filter has a cutoff frequency set to the maximum operational frequency of the electronically tunable filter.

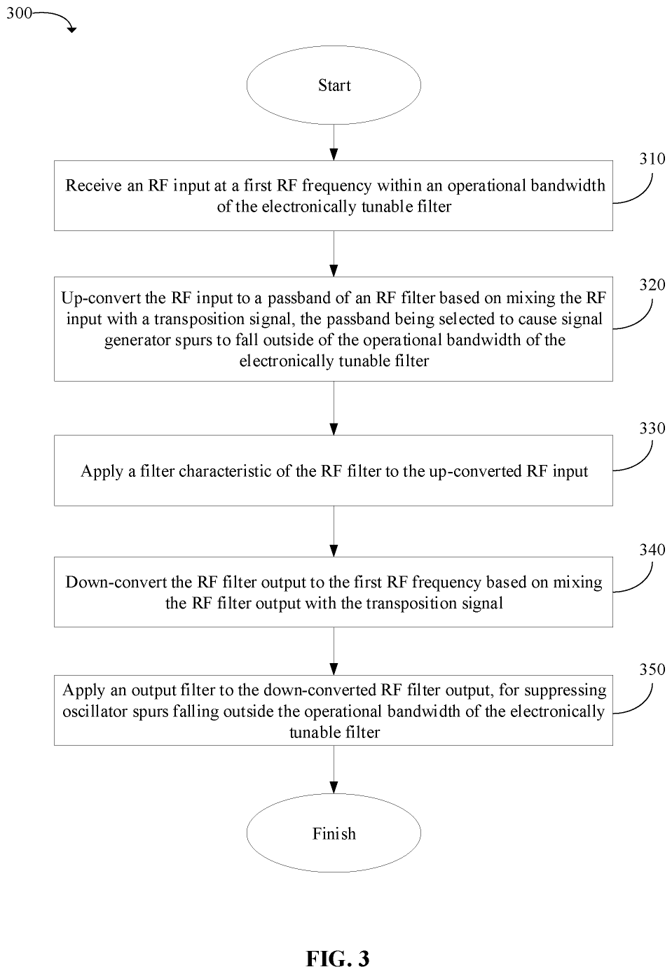

FIG. 4 illustrates an embodiment of a transposition network 400 for transposing an RF input f_{RFIN} to a component or set of components, such as an RF filter operating at a transposed or desired frequency, such as the center frequency of an RF filter. The transposition network comprises a first mixer 460a configured to receive a transposition signal f_{TS} selected for transposing the RF input f_{RFIN} to the transposed frequency. Thus, the RF input f_{RFIN} passes through the components at the transposed frequency and subsequently mixes with the transposition signal f_{TS} at a second mixer 460b, which provides an RF output f_{ROUT} at the original input frequency. Advantageously, frequency transposition enables transposing wideband inputs to fixed frequency components by selectively modifying the transposition signal to allow transposition to the desired frequency.

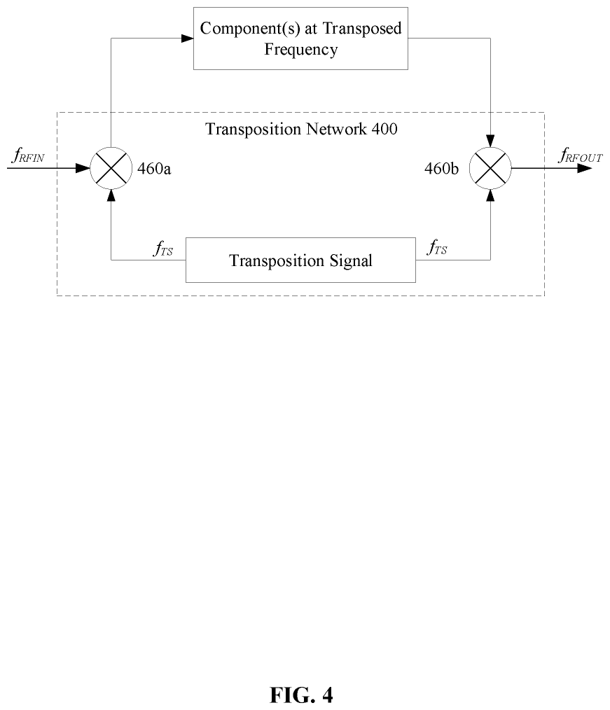

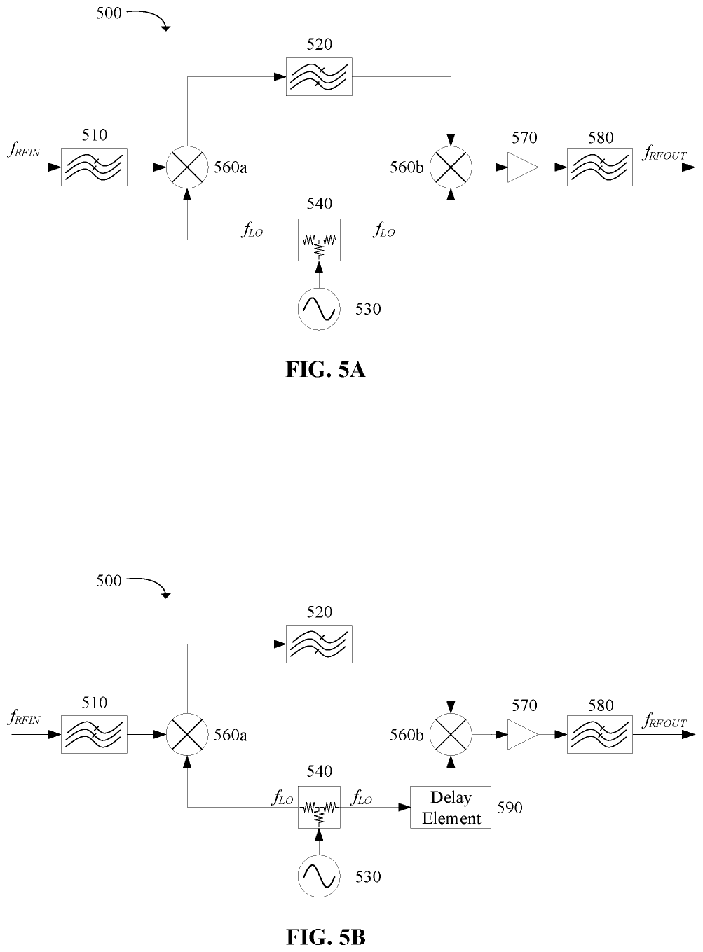

FIGS. 5A and 5B illustrate embodiments of a wideband electronically tunable filter 500 in accordance with the present disclosure. The filter 500 reverses operation of the frequency transposition described in relation to FIG. 1 and instead up-converts to filter at RF rather than down-converting to filter at IF. In the embodiment, the electronically tunable filter 500 comprises an input filter 510, RF filter 520, local oscillator 530, power splitter 540, up-conversion mixer 560a, down-conversion mixer 560b, amplifier 570, and output filter 580. In an embodiment, the mixers 560a and 560b comprise an image rejection mixer, or a double balance mixer. In an embodiment, the mixers 560a and 560b comprise a wideband mixer. In an embodiment, the wideband electronically tunable filter 500 is configured to implement the method 300. In an embodiment, the wideband electronically tunable filter is configured to implement one or more operations of the method 300. In an embodiment, the wideband electronically tunable filter 500 may further include a delay element 590 as illustrated in FIG. 5B and described further below.

The filter 500 receives an RF input f_{RFIN} which transmits to an input filter 510. In an embodiment, the input filter 510 comprises a low pass filter having a cutoff frequency which may set the operational bandwidth for the filter 500. For example, the input filter 510 may comprise a low pass filter having a cutoff frequency of 20 GHz, limiting the operating bandwidth of the filter 500 to RF inputs of 20 GHz or less. The up-conversion mixer 560a receives and up-converts the RF input f_{RFIN} to a desired RF frequency based on mixing with a transposition signal f_{LO} generated by a local oscillator 530. In an embodiment, the desired frequency falls within a filter bandwidth of the RF filter 520. In an embodiment, the desired frequency falls with a passband of the RF filter 520. In an embodiment, the desired frequency is a center frequency of the RF filter 520. In an embodiment, the RF filter 520 comprises a passband filter. The output of the RF filter 520 transmits to the down-conversion mixer 560b for transposition down to the original frequency of the filtered RF input f_{RFIN} and subsequent transmission to the amplifier 570 and the output filter 580 which provides the system output f_{RFOUT}. In an embodiment, the output filter 580 comprises a low pass filter having a cutoff frequency based on the operational bandwidth of the filter 500. In an embodiment the input filter 510 and the output filter 580 comprise a low pass filter having the same cutoff frequency. In an embodiment, the cutoff frequency is 20 GHz.

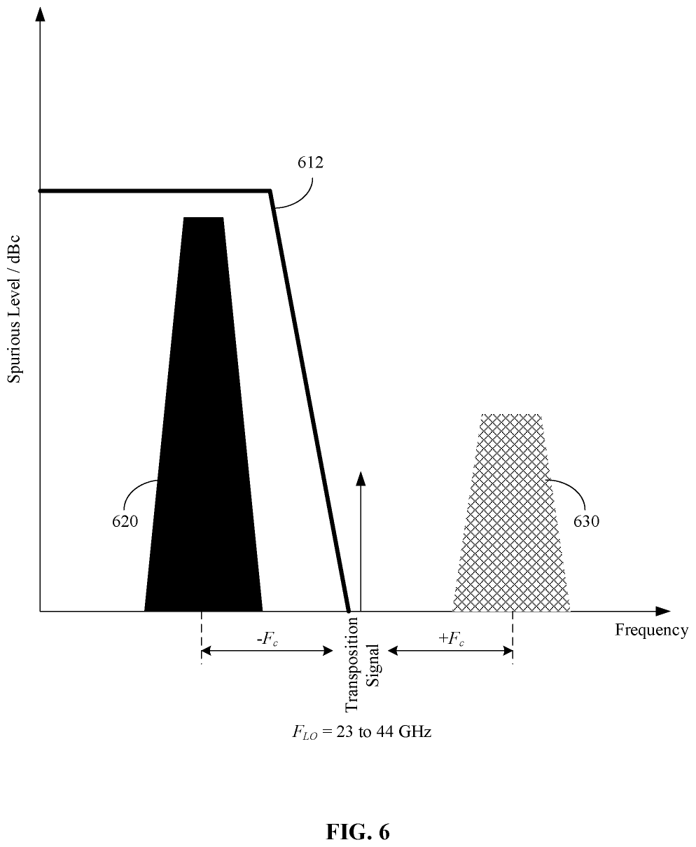

The desired frequency for transposition is selected to limit operation of the local oscillator 530 to a frequency band which does not-overlap with the operating band of the filter 500, for enhancing suppression of the local oscillator spurs, as further illustrated in FIG. 6. Consider a filter 500 having an operating bandwidth from 1-20 GHz. An RF filter 520 may be selected to have a passband which necessitates operating the local oscillator 530 in an RF band which does not overlap with the operating band of the filter 500. For example, the RF filter 520 may be selected to comprise a 2 GHz passband centered at 44 GHz for providing a filter characteristic which suppresses signals outside of a 43-45 GHz passband. Consequently, in order to transpose an RF input signal from 1-20 GHz up to the 43-45 GHz passband, the local oscillator 530 selectively operates in an RF band from 24 GHz to 43 GHz which does not-overlap with the operating band of the filter 500, thereby improving spurious performance. For example, the output filter 580 may comprise a low pass filter having a cutoff frequency of 20 GHz for suppressing local oscillator spurs which fall outside the operational bandwidth of the filter 500. Accordingly, up-converting the initial system input advantageously supports greater separation between the RF input f_{RFIN} and the local oscillator signal f_{LO}, eliminating the need for switched filter banks for sub-banding desired passbands, improving form factor, weight, and power consumption, whilst also improving spurious performance and allowing for simpler techniques to attenuate local oscillator spurs. For example, increasing the separation between the RF input and local oscillator signals has the effect of increasing the order of the mixing spurs that will fall in band. Consequently, increasing the operating band of the RF filter 520 improves the spurious free range of the resulting filter 500.

In an embodiment as illustrated in FIG. 5B, the filter 500 may include a delay element 590 coupled between the power splitter 540 and the down-conversion mixer 560b. The delay element 590 may be configured to match and/or compensate for a delay of the RF filter 520, to match and/or balance phase noise received at the inputs of the mixer 560b, resulting in an improvement in phase noise. Embodiments of a delay element 590 include but are not limited to, an identical matching filter to RF filter 520, a transmission delay line, a surface acoustic wave delay line and optical delay line configured with laser, electro-optical modulator, fiber optic delay line and photodetector to enable delay of the RF signal by modulation and demodulation of the optical signal passing through the fiber optical delay line. Embodiments of a tunable filter as further disclosed herein may similarly include a delay element configured to match and/or compensate for a delay of one or more elements implemented at a transposed frequency, whether at IF or RF.

FIG. 6 illustrates a plot of the output from a down-conversion mixer in accordance with an embodiment of the present disclosure, such as the down-conversion mixer 560b depicted in FIGS. 5A and 5B. In particular, FIG. 6 illustrates a transposition signal F_{LO}, a lower sideband output 620, and an upper sideband output 630. The sideband outputs are offset from the transposition frequency by an amount equal to the center frequency F_{c} of an RF filter, such as the RF filter 520. Consequently, increasing the center frequency F_{c} of the RF filter also increases the separation between the upper and lower sideband outputs of the down-conversion mixer. Though the lower sideband output 630 may meet spurious requirements for the system, the upper sideband output 620 may not meet such spurious requirements, necessitating suppression of the upper sideband output 620. Given that the operational band of the wideband ETF and the operating band of the local oscillator do not overlap, a low pass filter—such as the filter 580—may be configured to apply a filter characteristic 612 across the operational bandwidth of the filter 500, for readily suppressing the upper sideband output and the local oscillators spurs present in the output of the down-conversion mixer.

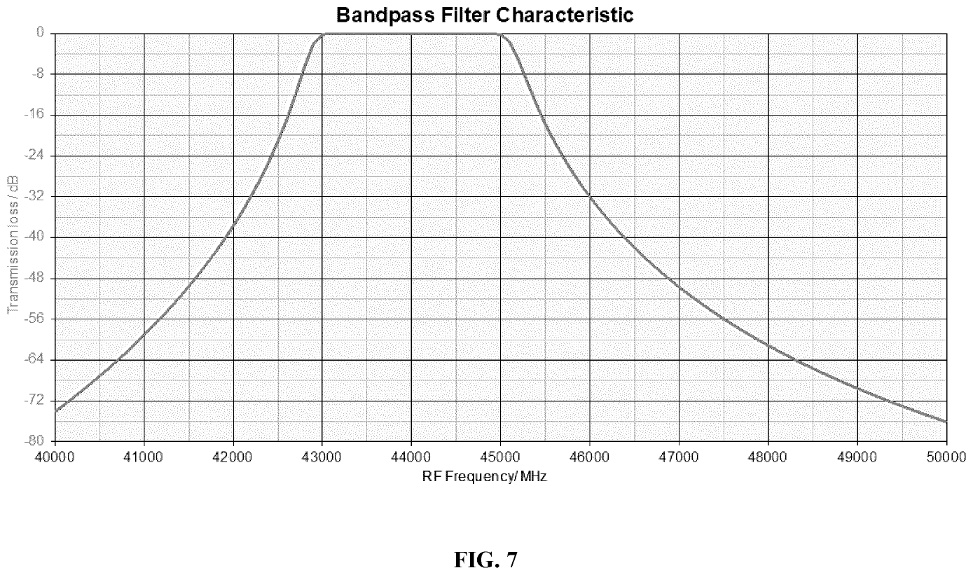

FIG. 7 is a plot of a simulated passband filter characteristic for a 9th order Chebyshev filter at RF, such as the RF filter 520, implemented in a wideband ETF up-converting to RF in accordance with the present disclosure. The Chebyshev filter is centered at 44 GHZ, and demonstrates a 0.1 dB transmission loss across an approximately 2 GHz passband from 43 GHz to 45 GHz. Signals outside the passband otherwise experience attenuation with the bandpass characteristic rolling off down to approximately −74 dB at 40 GHz, and −76 dB at 50 GHz.

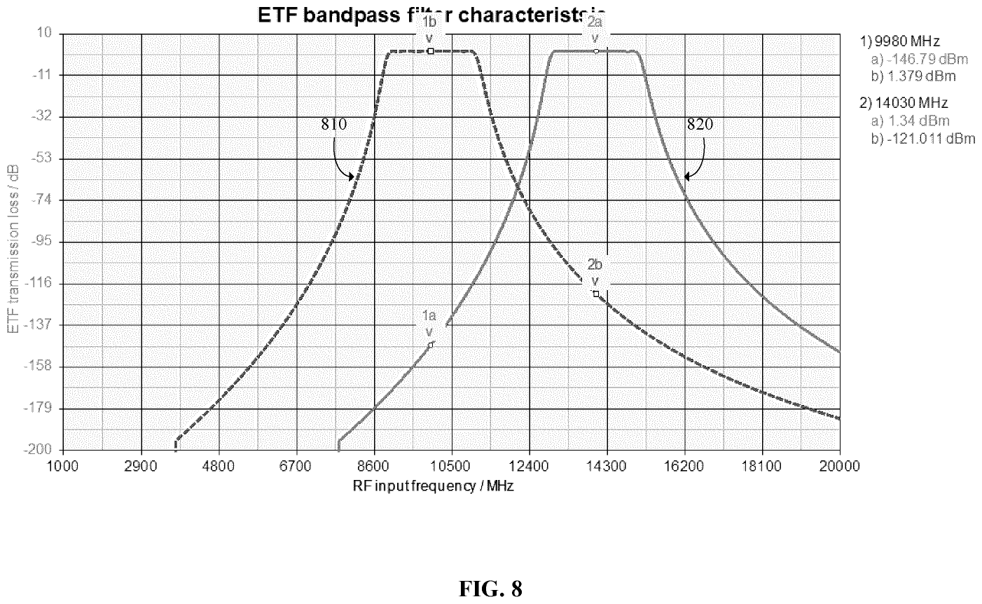

FIG. 8 illustrates two plots 810 and 820 corresponding to simulated RF passband characteristics transposed down from RF and respectively centered at 9980 MHz and 14030 MHz based on adjusting center frequency control through use of a local oscillator in accordance with embodiments of a wideband ETF as disclosed herein.

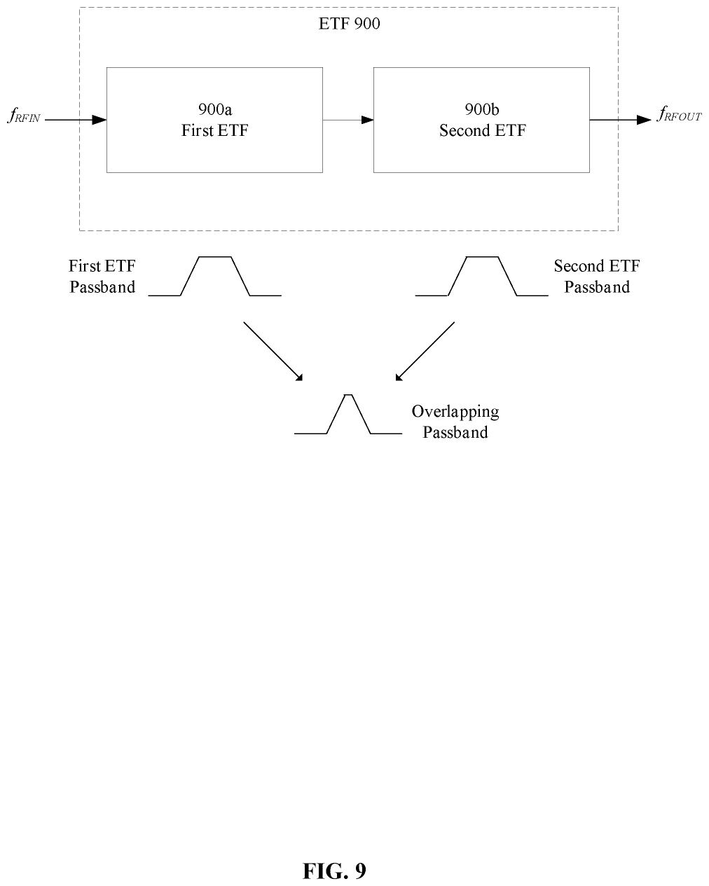

FIG. 9 is a block diagram of a wideband electronically tunable filter 900 comprising a series cascade of respective first and second electronically tunable filters 900a and 900b in accordance with embodiments of the present disclosure. For example, the first and second electronically tunable filters 900a and 900b may be wideband ETFs up-converting to RF in accordance with embodiments of the present disclosure, such as in accordance with the electronically tunable filter 500 illustrated in FIGS. 5A and 5B. Advantageously, cascading two ETFs in series provides an adjustable bandwidth filter based on overlapping the filter characteristics of each respective ETF. Furthermore, overlapping the filter characteristics of the respective filters may yield a narrower filter bandwidth than may be individually achievable by either ETF alone. In an embodiment, the minimum filter bandwidth that may be achieved is based on an attenuation gradient. For example, the minimum filter bandwidth for the ETF 900 may be a factor of 2 greater than the bandwidth required to achieve a particular attenuation. For example, if an individual ETF transition band achieves 40 dB attenuation in 100 MHz, then the minimum bandwidth to achieve 40 dB attenuation for the ETF 900 will be at least 200 MHz.

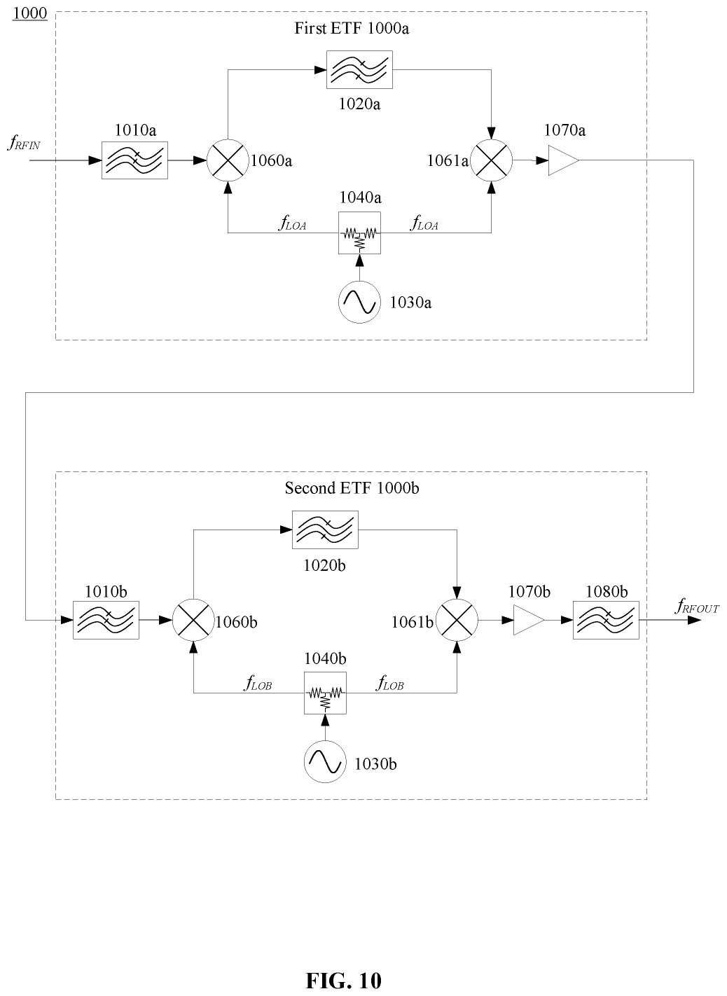

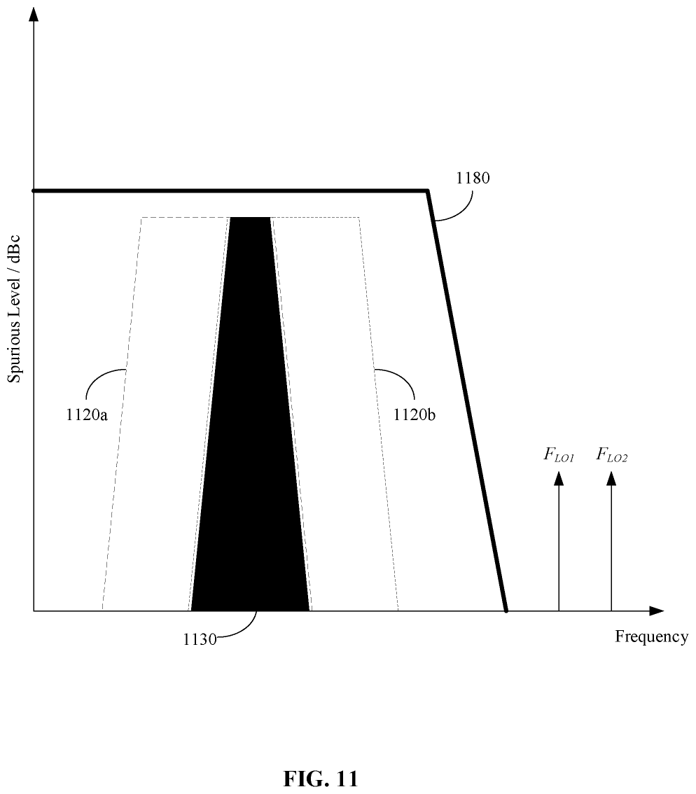

FIG. 10 is a schematic diagram of the wideband electronically tunable filter 1000 comprising respective first and second electronically tunable filters 1000a and 1000b cascaded in series, as similarly illustrated with respect to the wideband electronically tunable filter 900 comprising first and second electronically tunable filters 900a and 900b as illustrated in FIG. 9. The first ETF 1000a comprises an input filter 1010a, RF filter 1020a, local oscillator 1030a, power splitter 1040a, up-conversion mixer 1060a, down-conversion mixer 1061a, and amplifier 1070a, as may be similarly implemented as described with respect to the corresponding elements of the filter 500 of FIGS. 5A and 5B. Similarly, the second ETF 1000b comprises an input filter 1010b, RF filter 1020b, local oscillator 1030b, power splitter 1040b, up-conversion mixer 1060b, down-conversion mixer 1061b, amplifier 1070b, and output filter 1080b, as may be similarly implemented as described with respect to the corresponding elements of the filter 500 of FIGS. 5A and 5B. Respective local oscillators 1030a and 1030b may selectively adjust their output to provide center frequency tuning for shifting the filter characteristics of the first and second ETFs 1000a and 1000b, respectively. Adjusting the relative offset between the filter characteristics controls the amount of overlap between the two filter characteristics and thereby provides an overlapping adjustable passband for the wideband electronically tunable filter 1000, as further illustrated and described with respect to FIG. 11.

FIG. 11 is a plot of a passband characteristic 1130 based on overlapping filter characteristics 1120a and 1120b in accordance with an embodiment of the present disclosure. The passband characteristic 1130 may be derived, for example, using a wideband electronically tunable filter, such as the filter 900 of FIG. 9 or the filter 1000 of FIG. 10, whereby two ETFs are cascaded in series to provide an adjustable passband which varies based on a relative offset between the respective filter characteristics of the first and second ETFs. As illustrated in FIG. 11, a relative offset between the two filter characteristics may be adjusted based on adjusting respective local oscillator outputs F_{LO1} and F_{LO2} to provide a passband characteristic 1130 based on overlap between a first filter characteristic 1120a and a second filter characteristic 1120b. A low pass filter 1180 may be applied to further suppress the first and second local oscillator spurs corresponding to F_{LO1} and F_{LO2}.

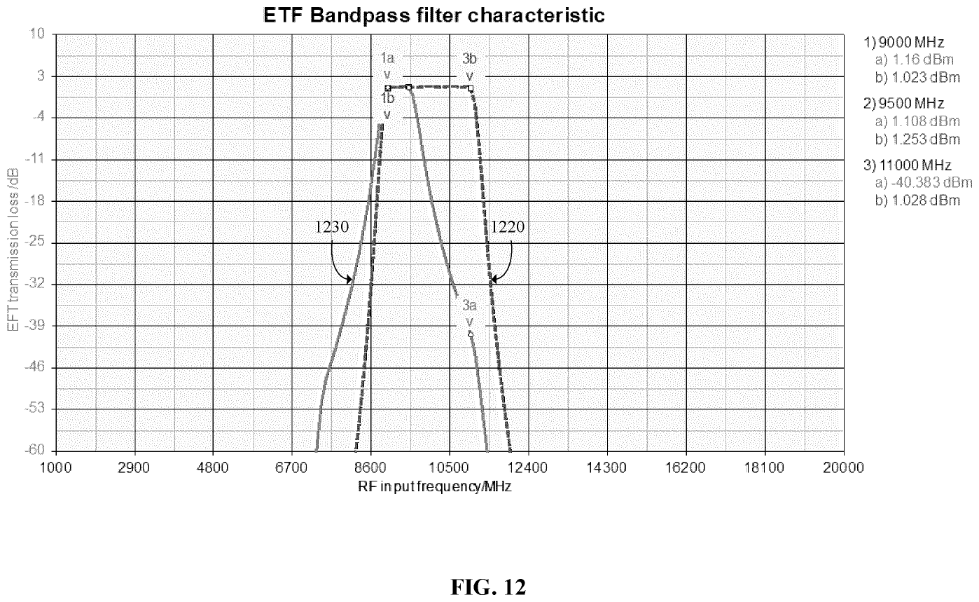

FIG. 12 is a plot of a simulated adjustable passband 1230 derived from offsetting two instances of a transposed filter characteristic 1220. As illustrated in FIG. 12, the adjustable passband has an approximately 1 dB transmission gain between about 8700 MHz and 9300 MHz as a result of amplification stages. Signals outside the passband otherwise experience attenuation with the passband characteristic 1230 rolling off down to approximately −60 dB at 7150 MHz, and −60 dB at 11450 MHz.

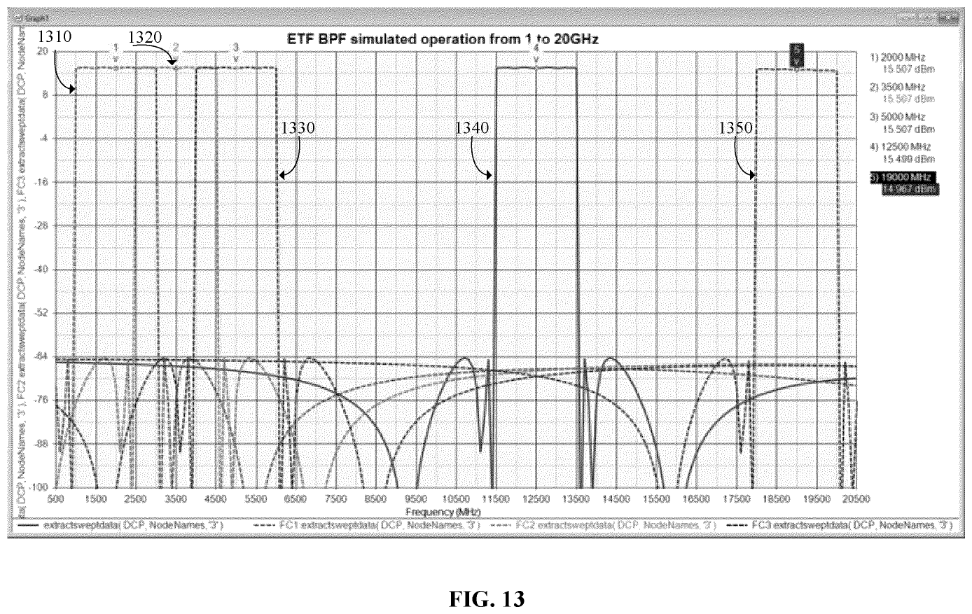

FIG. 13 is a plot of simulated transposed passband characteristics for an idealized 10 pole elliptic filter implemented in a wideband electronically tunable filter in accordance with the present disclosure. The elliptic filter is stepped in 1500 MHz intervals across a plurality of passband center frequencies located at 2000 MHz, 3500 MHZ, 5000 MHZ, 12500 MHz, and 19000 MHz respectively corresponding to plots 1310, 1320, 1330, 1340, and 1350.

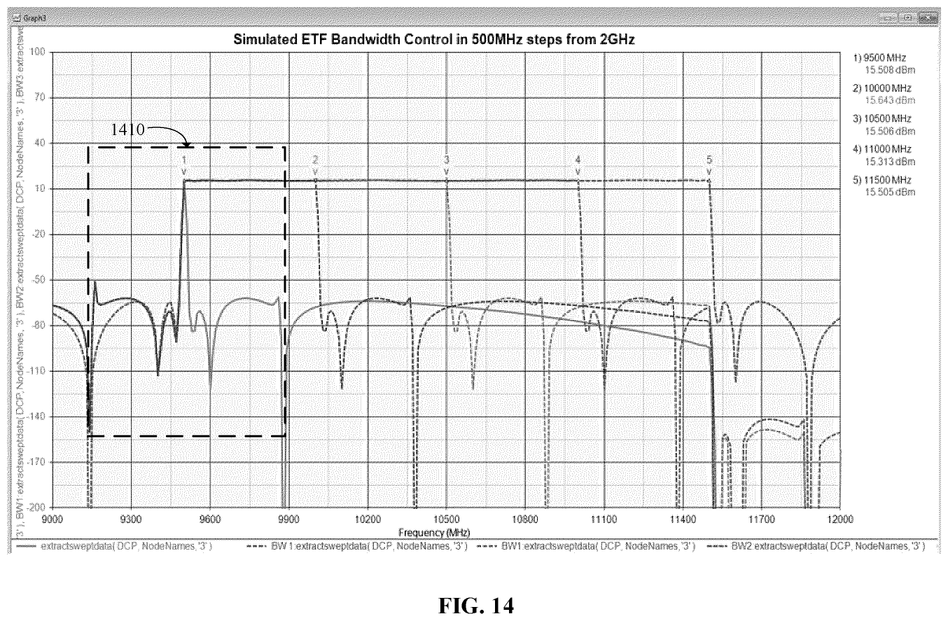

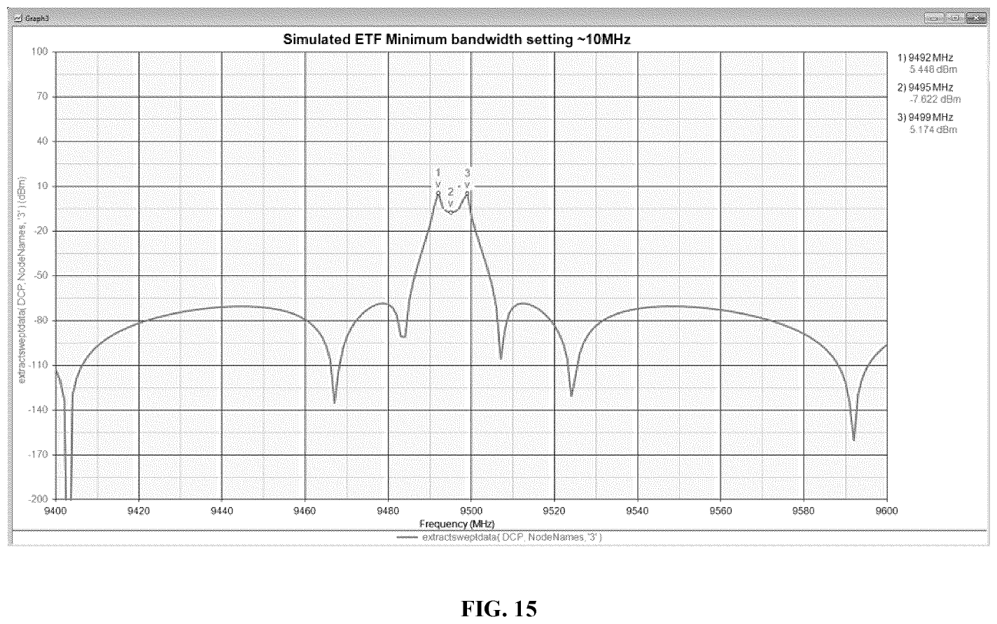

FIG. 14 is a plot of simulated transposed passband characteristics for an idealized 10 pole elliptic filter implemented in a wideband electronically tunable filter in accordance with the present disclosure. The elliptic filter bandwidth is increased in steps of 500 MHz from 500 MHz to 2 GHz extending the passband from 9500 MHz to 10000 MHz to 9500 MHz to 11500 MHz. FIG. 15 further illustrates an enlarged image of the viewing area 1410.

FIG. 15 is an enlarged view of the plot captured in the viewing area 1410 of FIG. 14. In particular, FIG. 15 illustrates a passband of about 10 MHz approximately spanning the points v1 and v2 and greater than 50 dB stop band 10 MHz from the filter band edge.

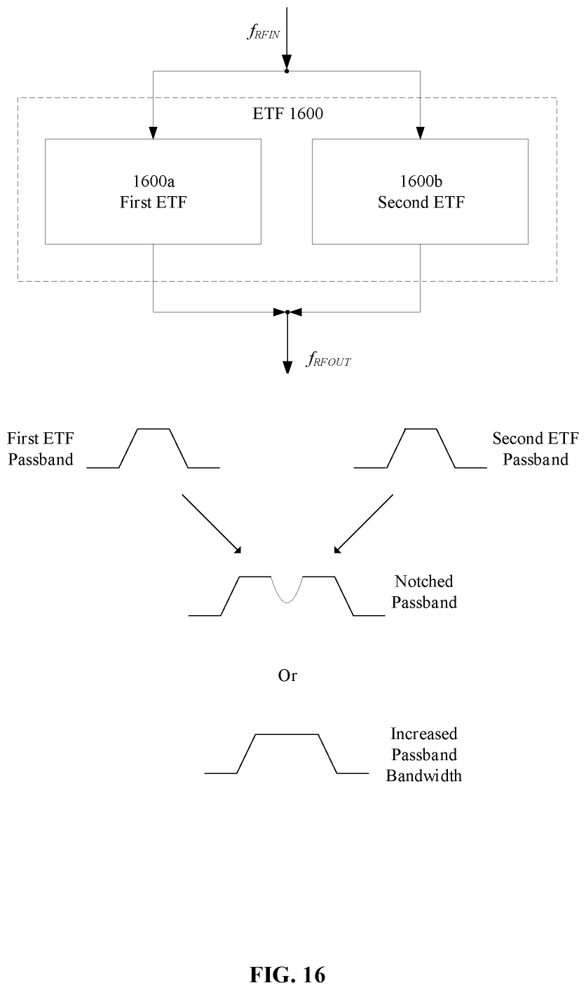

FIG. 16 is a block diagram of a wideband electronically tunable filter 1600 comprising a parallel configuration of respective first and second electronically tunable filters 1600a and 1600b in accordance with embodiments of the present disclosure. For example, the first and second electronically tunable filters 1600a and 1600b may be wideband ETFs up-converting to RF in accordance with embodiments of the present disclosure, such as in accordance with the electronically tunable filter 500 illustrated in FIGS. 5A and 5B. Advantageously, two ETFs in parallel provide an adjustable bandwidth filter based on the superposition of each respective EFT's filter characteristic. For example, a relative offset between the first and second ETFs may be adjusted to provide a filter characteristic for the ETF 1600 comprising a stop-band or notch for attenuating signals between the respective passbands of each filter; or, may be adjusted to provide a passband with a greater bandwidth than may otherwise be achieved individually by either ETF alone.

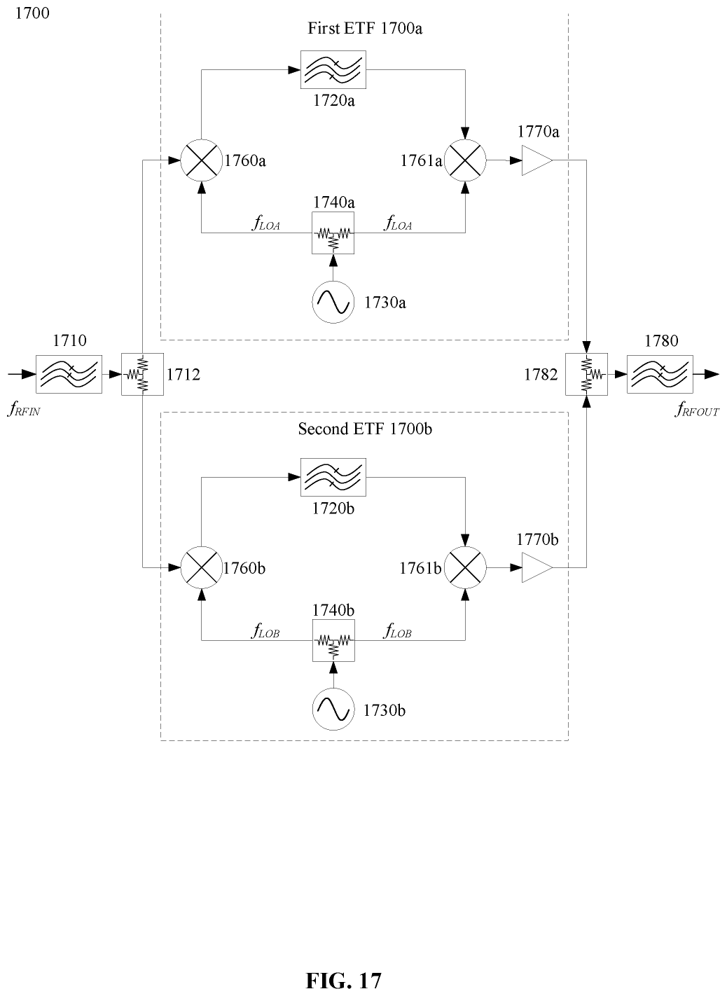

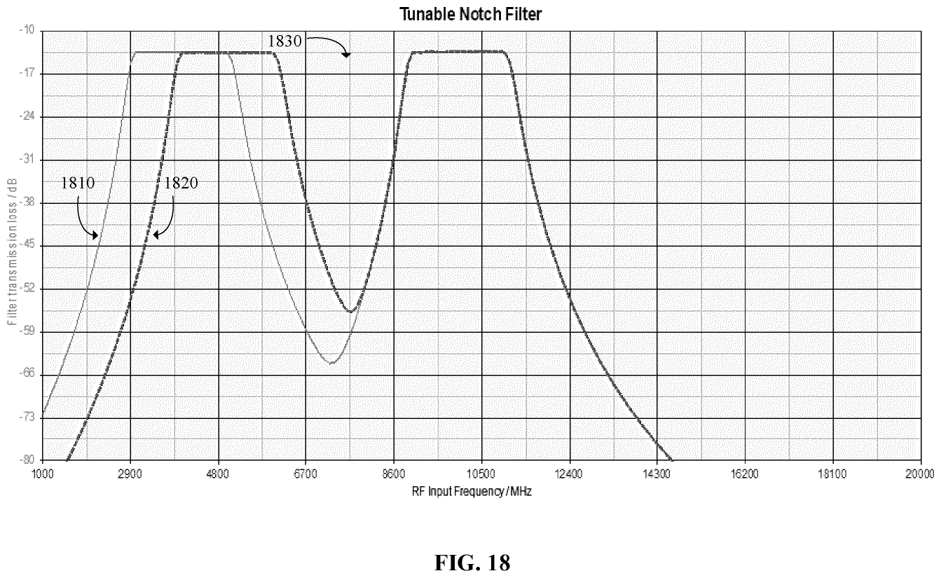

FIG. 17 is a schematic diagram of the wideband electronically tunable filter 1700 comprising a parallel configuration of respective first and second electronically tunable filters 1700a and 1700b in accordance with embodiments of the present disclosure, as similarly illustrated with respect to the wideband electronically tunable filter 1600 of FIG. 16 comprising respective first and second electronically tunable filters 1600a and 1600b. The first ETF 1700a comprises an RF filter 1720a, local oscillator 1730a, power splitter 1740a, up-conversion mixer 1760a, down-conversion mixer 1761a, and amplifier 1770a, as may be similarly implemented as described with respect to the corresponding elements of the filter 500 of FIGS. 5A and 5B. Similarly, the second ETF 1700b comprises an RF filter 1720b, local oscillator 1730b, power splitter 1740b, up-conversion mixer 1760b, down-conversion mixer 1761b, and amplifier 1770b, as may be similarly implemented as described with respect to the corresponding elements of the filter 500 of FIGS. 5A and 5B. The wideband filter 1700 further comprises respective input and output filters 1710 and 1780 as may be similarly implemented as described with respect to the corresponding elements of filter 500 of FIGS. 5A and 5B, for use as input and output filters for the first and second ETFs 1700a and 1700b. The respective input and output filters 1710 and 1780 further include corresponding power splitters 1712 and 1782. Respective local oscillators 1730a and 1730b may selectively adjust their output to provide center frequency tuning for shifting the filter characteristics of the first and second ETFs 1700a and 1700b, respectively. Adjusting the relative offset between the filter characteristics adjusts the resulting superposition of the two filter characteristics, providing an adjustable filter characteristic for the wideband electronically tunable filter 1700, as further illustrated and described with respect to FIG. 18. For example, increasing the relative center frequency offset between the first and second ETFs 1700a and 1700b may result in a passband for the filter 1700 having a stop-band or notch between the respective passbands of each individual ETF passband. Conversely, decreasing the relative center frequency offset between the first and second ETFs 1700a and 1700b may result in overlapping passbands and provide an increase in passband bandwidth for the filter 1700 greater than the individual passband bandwidth of either ETF alone. Advantageously, an adjustable stop-band in accordance with the present disclosure provides filters with capability to track and attenuate unwanted signals, such as jamming signals which may move dynamically in frequency.

FIG. 18 is a plot of simulated passband characteristics for a wideband electronically tunable filter having a first and second ETF configured in parallel in accordance with the present disclosure, such as the wideband filters 1600 and 1700 illustrated in FIGS. 16 and 17, respectively. The plot includes a first passband characteristic 1810 based on the superposition of two transposed filter characteristics centered at approximately 4000 MHz and 10000 MHz; and, a second passband characteristic 1820 based on the superposition of two transposed filter characteristics centered at approximately 5000 MHz and 10000 MHz. Each passband characteristic further includes a stopband or notch 1830 for attenuating signals outside the passbands, increasing in size proportionally to the relative center frequency offset between the two respective transposed filter characteristics. For example, the first passband characteristic 1810 has a 6000 MHz center frequency offset which is relatively larger than the 5000 MHz center frequency offset of the second passband characteristic 1820. Consequently, the stopband 1830 for the first passband characteristic 1810 is relatively larger than the stopband 1830 for the second passband characteristic 1820.

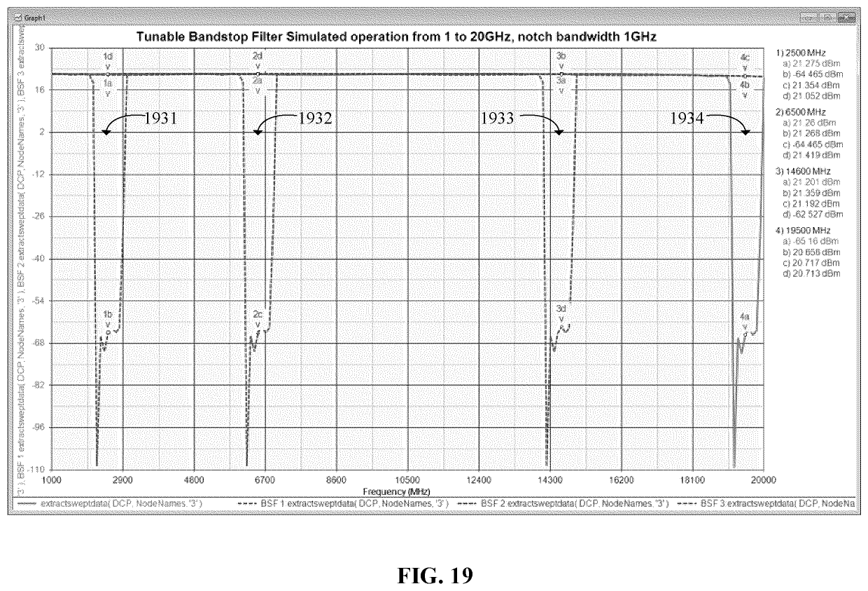

FIG. 19 is a plot of simulated passband characteristics for a wideband electronically tunable filter having a first and second ETF configured in parallel in accordance with the present disclosure, such as the wideband filters 1600 and 1700 illustrated in FIGS. 16 and 17, respectively. The plot overlays various passband characteristics across a 1-20 GHz operational bandwidth of the wideband filter, each passband characteristic having a corresponding stopband based on a relative center frequency offset between two transposed filter characteristics that are correspondingly shifted across the operational bandwidth. In particular, FIG. 19 illustrates a plurality of stopbands 1931, 1932, 1933, and 1934 corresponding to offset transposed filter characteristics.

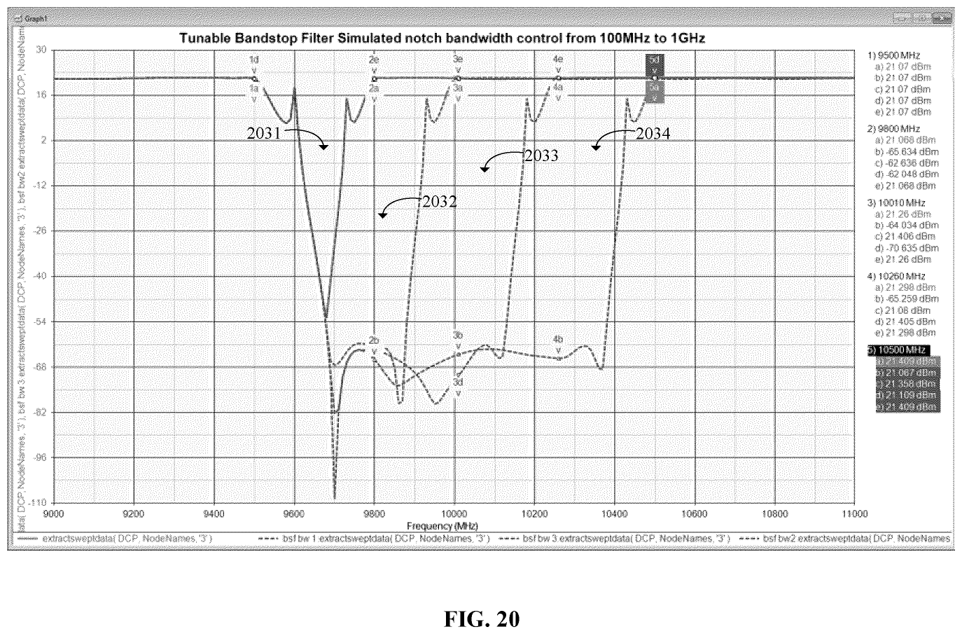

FIG. 20 is a plot of a simulated passband characteristic for a wideband electronically tunable filter having a first and second ETF configured in parallel in accordance with the present disclosure, such as the wideband filters 1600 and 1700 illustrated in FIGS. 16 and 17, respectively. The plot demonstrates adjusting the relative center frequency offset between two transposed filter characteristics to provide correspondingly adjusted stopbands 2031, 2032, 2033, and 2034 of approximately 100 MHz, 250 MHz, 550 MHz, and 1 GHz in width, respectively.

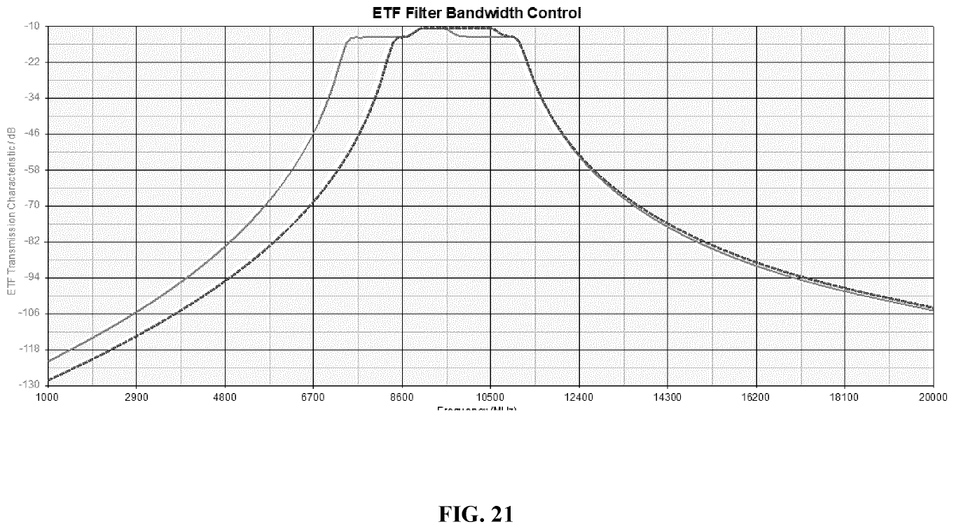

FIG. 21 is a plot of a simulated passband characteristic for a wideband electronically tunable filter having a first and second ETF configured in parallel in accordance with the present disclosure, such as the wideband filters 1600 and 1700 illustrated in FIGS. 16 and 17, respectively. The passband characteristic includes the superposition of a first transposed filter characteristic 2110 centered at approximately 9000 MHz; and, a second transposed filter characteristic 2120 centered at approximately 10 GHz. The overlapping superposition of the two filter characteristics 2110 and 2120 results in an increased operational bandwidth for the wideband electronically tunable filter.

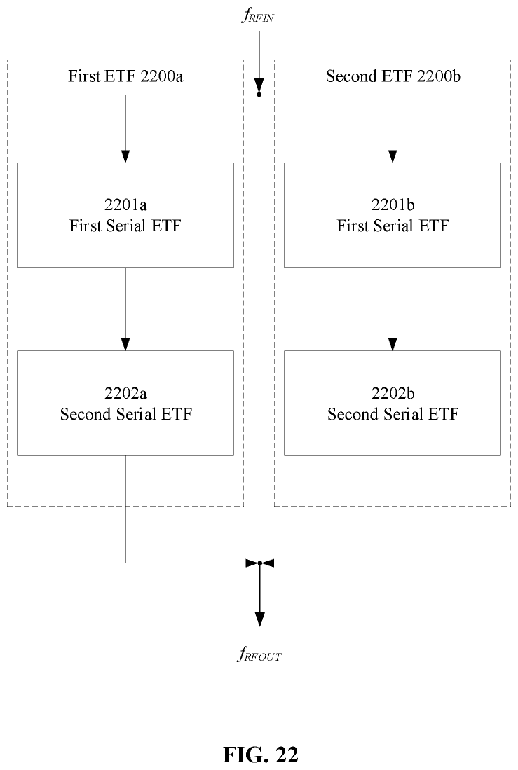

FIG. 22 is a block diagram of a wideband electronically tunable filter 2200 comprising a parallel configuration of respective first and second electronically tunable filters 2200a and 2200b, which each comprise serially cascaded first and second ETFs 2201a/2202 and 2201b/2202b, respectively. The filter 2200 advantageously leverages serial and parallel architectures together in a single embodiment, such as the serial and parallel architectures described and illustrated for example in relation to the wideband electronically tunable filters 900, 1000, 1600, and 1700 of respective FIGS. 9, 10, 16, and 17. Advantageously, the filter 2200 may thus leverage adjust narrow bandwidth control through overlap of serially cascaded filters in combination with leveraging an adjustable stopband derivable from the superposition of the ETF passband characteristics in parallel.

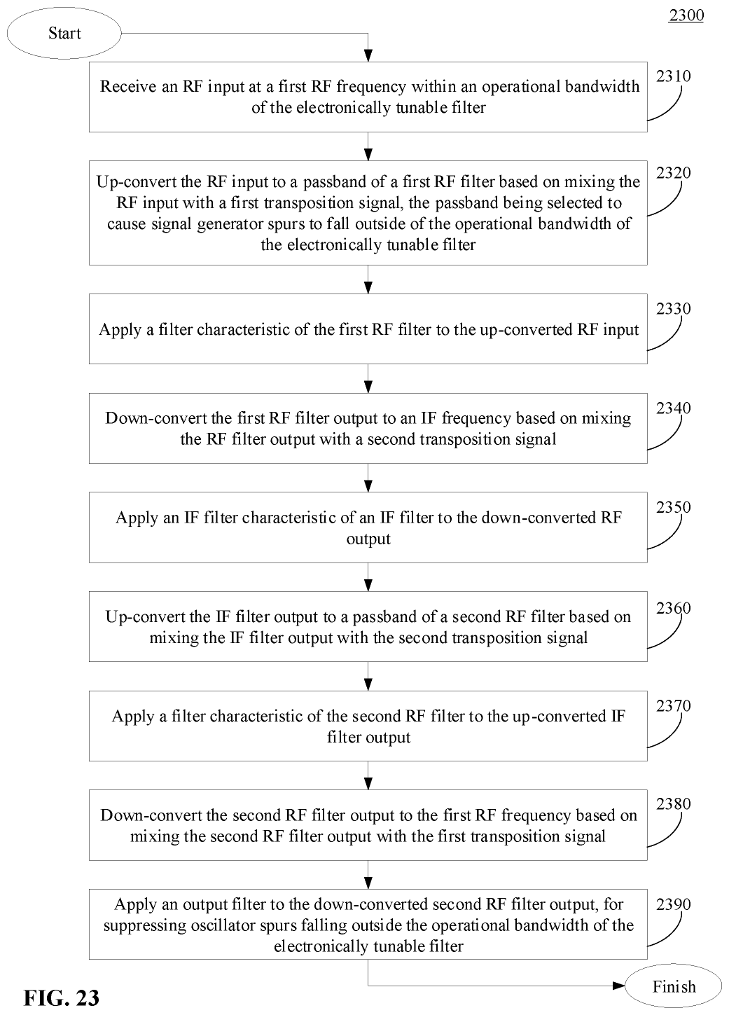

FIG. 23 illustrates a method 2300 for implementing a wideband electronically tunable filter having a nested electronically tunable filter at IF in accordance with an embodiment of the present disclosure. The operation of the method 2300 is not intended to be limiting but rather illustrates an example of nesting an electronically tunable filter at IF within a wideband electronically tunable filter. In some embodiments, the method 2300 may be accomplished with one or more additional operations not described, and/or without one or more of the operations described. Similarly, the order in which the operation of method 2300 is illustrated and described below is not intended to be limiting, but rather illustrative of an example of implementing a wideband electronically tunable filter having a nested electronically tunable filter at IF.

In some embodiments, the method 2300 may be implemented in one or more processing devices (e.g., a digital processor, an analog processor, a digital circuit designed to process information, an analog circuit designed to process information, a computing network implemented in the cloud, a state machine, and/or other mechanisms for electronically processing information). The one or more processing devices may include one or more devices executing some or all of the operations of the method 2300 in response to instructions stored electronically on an electronic storage medium. The one or more processing devices may include one or more devices configured through hardware, firmware, and/or software to be specifically designed for execution of one or more of the operations of the method 2300.

Advantageously, operations in accordance with the method 2300 perform two transposition functions, enabling nesting of an electronically tunable filter at IF which advantageously leverages the improved spurious performance obtained from a first transposition function from an input RF to a higher RF, and leverages improved filtering capabilities at IF through a second transposition function down from the higher RF to IF. Consequently, wideband nested ETF embodiments may more readily address system requirements for providing narrow passbands across broadband inputs through use of IF filters while maintaining the improved spurious performance obtained from implementing the operating bandwidths of the electronically tunable filter and the transposition signal generator in a non-overlapping manner. The reduced operating frequency of the electronically tunable filter nested at IF also enable the use of lower power consumption IF amplifiers to compensate for the overall losses of the filter. Furthermore, at the relatively lower IF frequency, the IF amplifier technology costs significantly less to implement relative to amplification at either the input RF frequency or the up converted RF frequencies used throughout the ETF.

The method 2300 may include an operation 2310 for receiving an RF input at a first RF frequency within an operating bandwidth of the electronically tunable filter. In an embodiment, the operational bandwidth of the wideband electronically tunable filter is set by low pass-filters at an input and an output of the electronically tunable filters. In an embodiment, the operational bandwidth is 1-20 GHz.

The method 2300 may include an operation 2320 for up-converting the RF input to a passband of a first RF filter based on mixing the RF input with a first transposition signal generated by a first signal generator, such as may be generated by a local oscillator. The first RF filter is selected to have a passband which limits the first signal generator to operate in an RF band outside of the operational bandwidth of the electronically tunable filter, advantageously causing signal generator spurs to similarly fall outside the operational bandwidth of the electronically tunable filter. In an embodiment, the first RF filter is selected to have a 2 GHz passband centered at 44 GHz. In an embodiment, the electronically tunable filter operational bandwidth is 1-20 GHz, the first RF filter is selected to have a 2 GHz passband centered at 44 GHz, and the first signal generator is limited to operate from 24-43 GHz in order to transpose an RF input to a passband of the first RF filter.

The method 2300 may include an operation 2330 for applying an RF filter characteristic of the first RF filter to the up-converted RF input. In an embodiment, the first RF filter comprises a bandpass filter. In an embodiment, the first RF filter may comprise a cavity filter, a waveguide filter, a microstrip filter, an MMIC filter, or combinations thereof. For example, depending on bandwidth and transition band requirements, the first RF filter may comprise an MMIC filter, providing smaller form factor relative to other RF filters.

The method 2300 may include an operation 2340 for down-converting the first RF filter output to an electronically tunable filter nested at an IF frequency. For example, the operation 2340 may down-convert the first RF filter output to an IF frequency of an IF frequency band based on mixing the first RF filter output with a second transposition signal generated by a second signal generator, such as may be generated by a local oscillator. In an embodiment, the IF frequency is between about 800 MHz and about 1100 MHz. In an embodiment, a lower end of the IF frequency band is about 240 MHz wherein a bandwidth of the IF filter is about 150 kHz. In an embodiment, an upper end of the IF frequency band is about 2,350 MHz wherein a bandwidth of the IF filter is about 150 MHz. In an embodiment, the IF filter comprises a SAW filter and the IF band is based on an operational bandwidth of the SAW filter. In an embodiment, the IF filter comprises a wideband IF filter wherein a center frequency of the IF filter falls within an IF band between 1 GHz and 10 GHz and providing operational bandwidth control up to 500 MHz.

The method 2300 may include an operation 2350 for applying an IF filter characteristic of an IF filter to the down-converted first RF Filter output. In an embodiment, the IF filter may comprise a surface acoustic wave (SAW) filter, a multi-pole ceramic resonator filter, a microstrip filter, a crystal filter, or combinations thereof.

The method 2300 may include an operation 2360 for up-converting the IF filter output to a passband of a second RF filter based on mixing the IF filter output with the first transposition signal generated by the first signal generator. The second RF filter is selected similarly to the first RF filter to have a passband which limits the first signal generator to operate in an RF band outside of the operational bandwidth of the electronically tunable filter, advantageously causing signal generator spurs to fall outside the operational bandwidth of the electronically tunable filter. In an embodiment, the second RF filter is selected to have the same passband as the first RF filter.

The method 2300 may include an operation 2370 for applying an RF filter characteristic of the second RF filter to the up-converted IF filter output. In an embodiment, the second RF filter comprises a bandpass filter. In an embodiment, the second RF filter may comprise a cavity filter, a waveguide filter, a microstrip filter, an MMIC filter, or combinations thereof. For example, depending on bandwidth and transition band requirements, the second RF filter may comprise an MMIC filter, providing smaller form factor relative to other RF filters.

The method 2300 may include an operation 2380 for down-converting the second RF filter output to the first RF frequency based on mixing the second RF filter output with the first transposition signal.

The method 2300 may include an operation 2390 for applying an output filter to the down-converted second RF filter output, for suppressing oscillator spurs falling outside the operational bandwidth of the electronically tunable filter. In an embodiment, the output filter is a low pass filter. In an embodiment, the output filter has a cutoff frequency set to the maximum operational frequency of the electronically tunable filter.

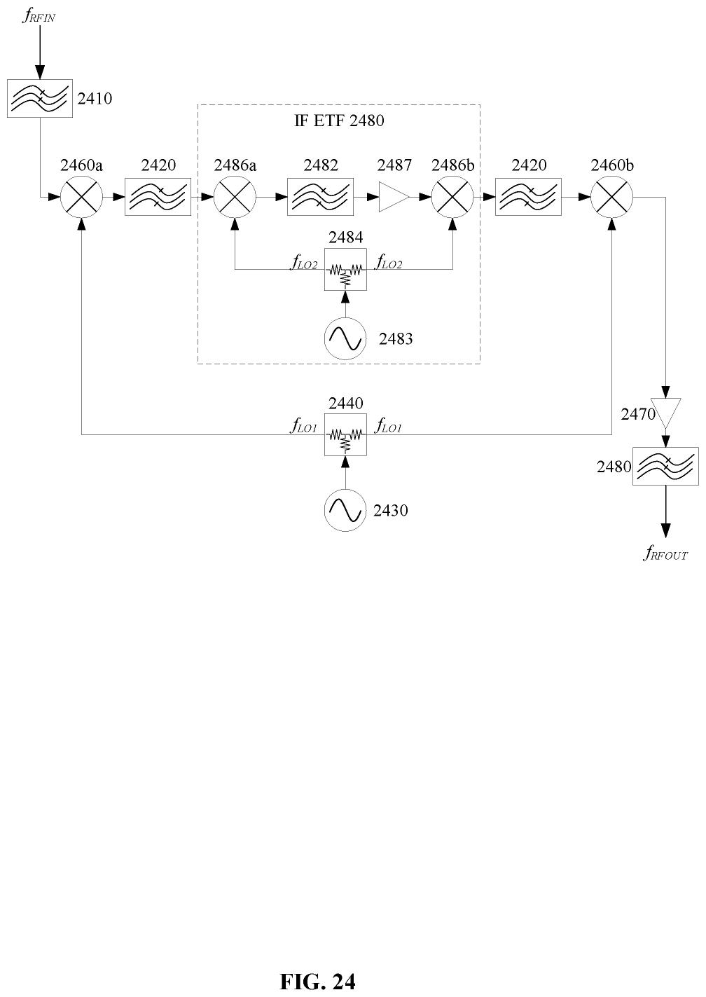

FIG. 24 is an embodiment of a wideband electronically tunable filter 2400 comprising a nested electronically tunable filter 2480 operating at IF. The wideband electronically tunable filter comprises an input filter 2410, RF filters 2420, a local oscillator 2430, a power splitter 2440, an up-conversion mixer 2460a, a down-conversion mixer 2460b, an amplifier 2470, and an output filter 2480, as may be similarly implemented as described with respect to the corresponding elements of the filter 500 of FIGS. 5A and 5B; for example, by providing improvements in spurious performance based on selecting the RF filters 2420 to have a passband or center frequency which limits operation of the local oscillator 2430 to an RF band which does not overlap with the operational bandwidth of the filter 2400. The filter 2400 further comprises an IF electronically tunable filter 2480 nested between the RF filters 2420. The nested IF ETF 2480 comprises an IF filter 2482, local oscillator 2483, power splitter 2484, down-conversion mixer 2486a, up-conversion mixer 2486b, and an amplifier 2487. The local oscillator selectively outputs a transposition signal f_{LO2} to allow transposition of an output of the RF filter 2420 down to IF, to leverage improvements in filters that may be more readily implemented at IF and otherwise inoperable at RF. For example, filters implemented at IF may exhibit smaller form factors, greater Q factors, lower power consumption, and/or improved transition band roll off characteristics. The reduced operating frequency of the electronically tunable filter nested at IF also enable the use of lower power consumption IF amplifiers, such as the IF amplifier 2487, to compensate for the overall losses of the filter. Furthermore, at the relatively lower IF frequency, the IF amplifier technology costs significantly less to implement relative to amplification at either the input RF frequency or the up converted RF frequencies used throughout the ETF. Embodiments of an IF filter may comprise a surface acoustic wave (SAW) filter, a multi-pole ceramic resonator filter, a microstrip filter, a crystal filter, or combinations thereof.

The wideband electronically tunable filter 2400 implements a first transposition function to RF to increase the spurious free operational bandwidth of the electronically tunable filter 2400 in accordance with embodiments of the present disclosure. For example, the passband or center frequency for the RF filter 2420 is selected to limit operation of the local oscillator 2430 to an RF band which does not overlap with the operating bandwidth of the filter 2400, providing improvements in the ability to suppress local oscillator spurs present in the output of the up-conversion mixer 2460a, thereby improving the spurious performance of the electronically tunable filter 2400 and allowing for wideband inputs without needing to implement a switched filter banks. The electronically tunable filter 2400 further comprises a second transposition function from RF down to IF, wherein an electronically tunable filter 2480 is implemented at IF to leverage filters with higher Q factors, sharper roll-off characteristics, narrower passbands, and/or other desirable filtering traits and filters than may otherwise not be achievable or operable at RF. The output of the IF ETF 2480 is transposed back to RF and subsequently transposed back down to the original input frequency where an output filter 2480 is applied to suppress local oscillator spurs outside the operational bandwidth of the electronically tunable filter 2400. Accordingly, the two transposition functions enable a nested electronically tunable filter embodiment which advantageously leverages improved spurious performance from transposing up to RF and, leverages improved filtering capabilities at IF through transposing down to IF. Consequently, nested ETF embodiments may more readily address system requirements for providing narrow passbands across broadband inputs.

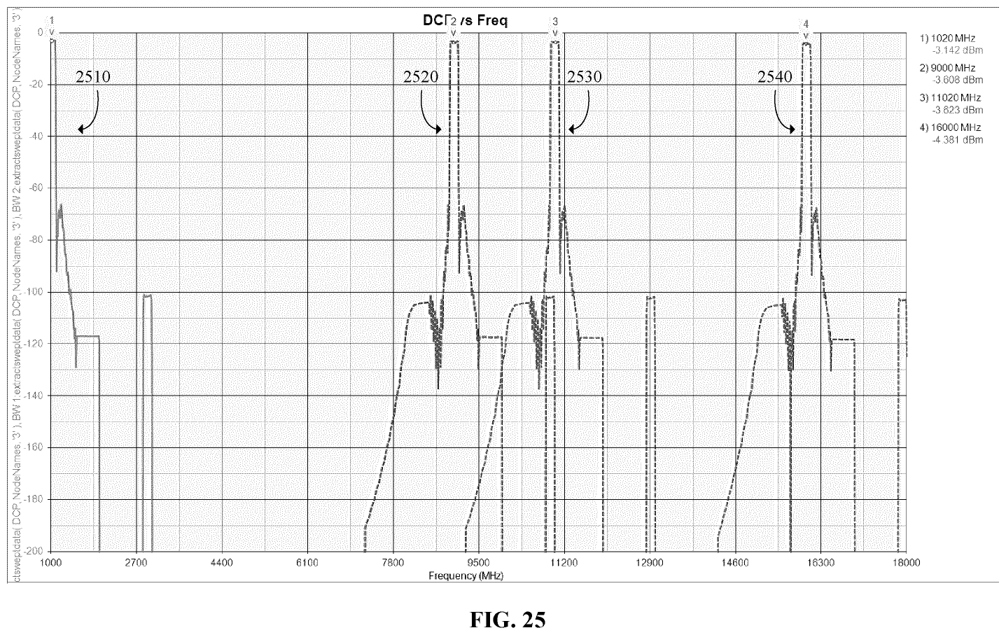

FIG. 25 illustrates four plots 2510, 2520, 2530, and 2540 corresponding to simulated IF passband characteristics transposed up from IF and respectively centered at 1020 MHz, 9000 MHz, 11020 MHz, and 16000 MHz, based on adjusting center frequency control through use of a local oscillator in accordance with embodiments of a wideband ETF having a nested electronically tunable filter implemented at IF as disclosed herein. Advantageously, the IF passbands transposed to RF demonstrate sharper roll-off characteristics provided by IF filters.

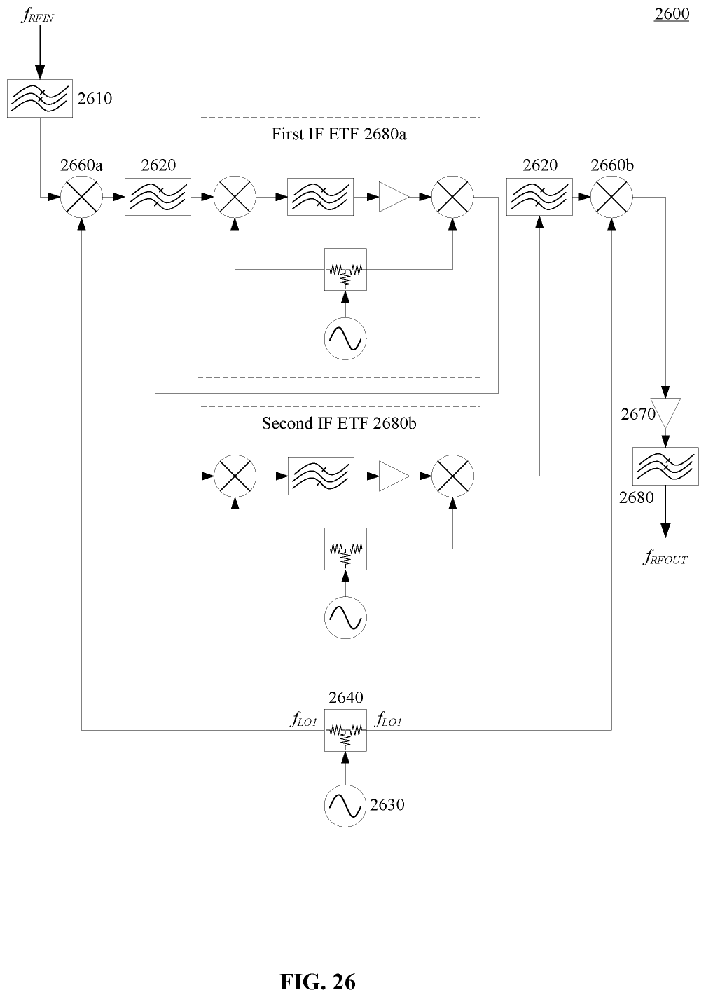

FIG. 26 is an embodiment of a wideband electronically tunable filter 2600 comprising a two nested electronically tunable filters 2680a and 2680b cascaded in series and operating at IF. The wideband electronically tunable filter comprises an input filter 2610, RF filters 2620, a local oscillator 2630, a power splitter 2640, an up-conversion mixer 2660a, a down-conversion mixer 2660b, an amplifier 2670, and an output filter 2680, as may be similarly implemented as described with respect to the corresponding elements of the filter 2400 of FIG. 24; for example, by providing improvements in spurious performance based on implementing the RF filters 2620 to have a passband or center frequency selected for limiting operation of the local oscillator 2630 to an RF band which does not overlap with the operational bandwidth of the filter 2600. The first and second IF ETFs 2680a and 2480b may be similarly implemented as described with respect to the IF ETF 2480 and its corresponding elements, as illustrated in FIG. 24. Advantageously, serially cascading two ETFs at IF leverages both the advantages of IF filters and an adjustable passband defined by the transposed filter characteristics of the first and second ETFs 2680a and 2680b in accordance with embodiments of the present disclosure. Other nested embodiments may include providing the first and second IF ETFs 2680a and 2680b in a parallel configuration rather than a serial configuration, or, may include a plurality of ETFs nested at IF to implement both serial and parallel configurations. Embodiments of a nesting two serially cascaded electronically tunable filters at IF have been demonstrated to enable bandwidth control from about 10 MHz to about 150 MHz.

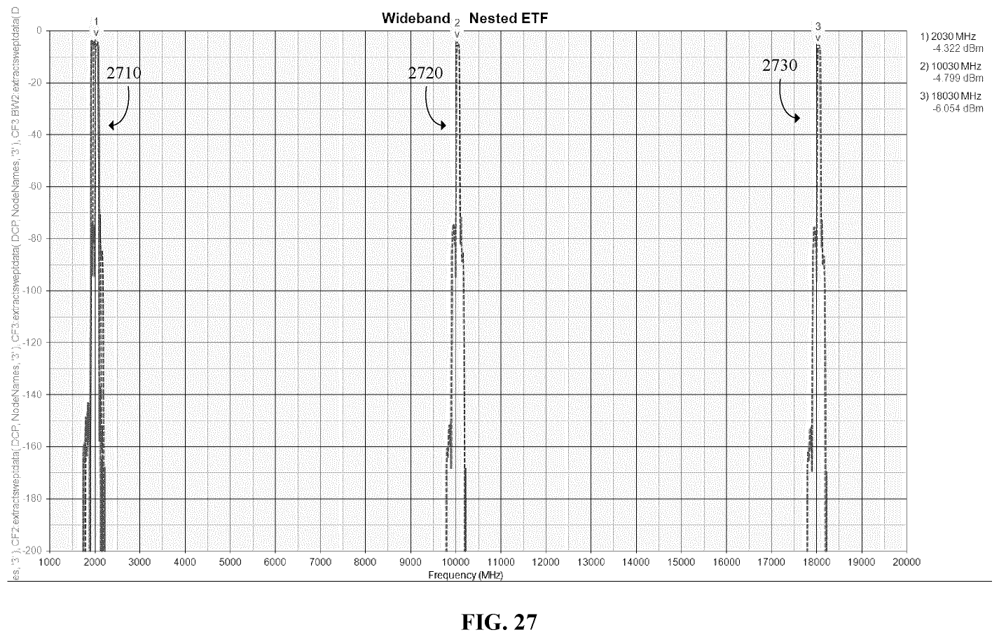

FIG. 27 plots three simulated adjustable passband characteristics 2710, 2720, and 2730 derived from cascading two electronically tunable filters nested in series at IF in accordance with an embodiment of the present disclosure. As illustrated in FIG. 27, the adjustable passband characteristics 2710, 2720, and 2730 define narrow passbands having sharp roll off characteristics centered respectively at 2030 MHz, 10030 MHz, and 18030 MHz.

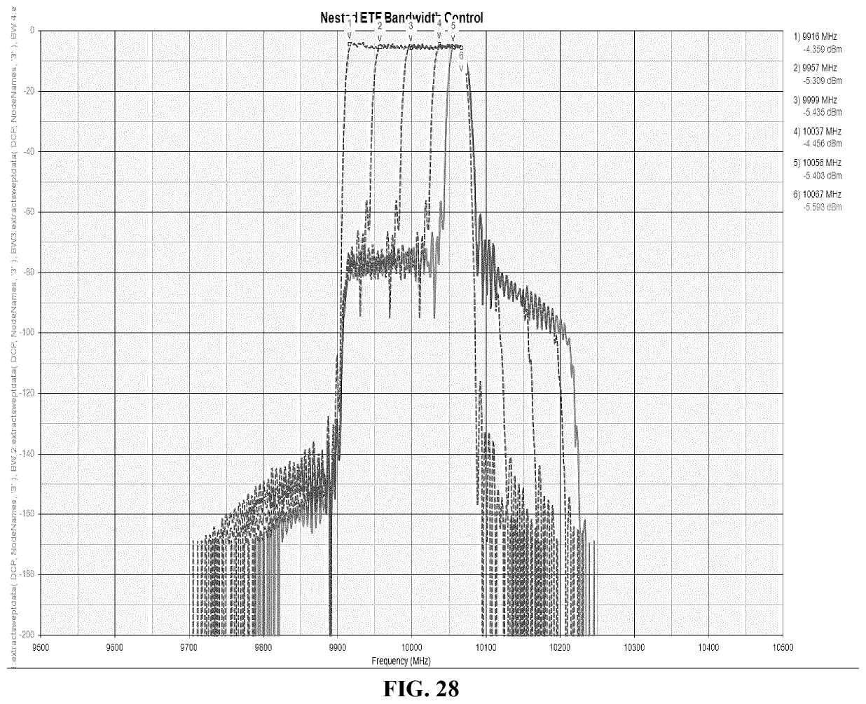

FIG. 28 is a plot of simulating adjusting a filter bandwidth from 10067 MHz to 10037 MHz corresponding to a filter passband of 11 MHz, to a filter bandwidth from 10067 MHz to 9916 MHz corresponding to a filter passband of 151 MHz for a wideband electronically tunable filter having a narrow passband characteristic nested at IF in accordance with an embodiment of the present disclosure. In particular, the passband characteristics v1, v2, v3, v4, v5, and v6 correspond to passband bandwidths of 151 MHz, 110 MHz, 68 MHz, 30 MHz, and 11 MHz, respectively.

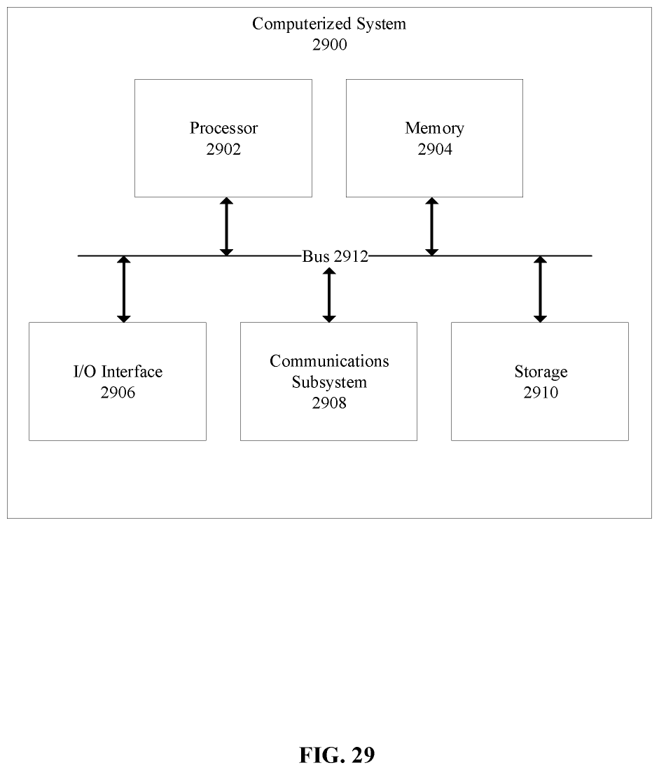

FIG. 29 is a block diagram of an example computerized device or system 2900 that may be used in implementing one or more aspects or components of an embodiment of a wideband electronically tunable filter in accordance with the present disclosure, for example implementing one or more elements, or sub-components, of an electronically tunable filter as disclosed herein, such as for example, the electronically tunable filters 100a, 100b, 500, 900, 1000, 1600, 1700, 2200, 2400, and 2600; and/or, for example, for use in implementing one or more operations of the methods 300 and 2300.

Computerized system 2900 may include one or more of a processor 2902, memory 2904, a mass storage device 2910, an input/output (I/O) interface 2906, and a communications subsystem 2908. Further, system 2900 may comprise multiples, for example multiple processors 2902, and/or multiple memories 2904, etc. Processor 2902 may comprise one or more of a digital processor, an analog processor, a digital circuit designed to process information, an analog circuit designed to process information, a state machine, and/or other mechanisms for electronically processing information. These processing units may be physically located within the same device, or the processor 2902 may represent processing functionality of a plurality of devices operating in coordination. The processor 2902 may be configured to execute modules by software; hardware; firmware; some combination of software, hardware, and/or firmware; and/or other mechanisms for configuring processing capabilities on the processor 2902, or to otherwise perform the functionality attributed to the module and may include one or more physical processors during execution of processor readable instructions, the processor readable instructions, circuitry, hardware, storage media, or any other components.

One or more of the components or subsystems of computerized system 2900 may be interconnected by way of one or more buses 2912 or in any other suitable manner.

The bus 2912 may be one or more of any type of several bus architectures including a memory bus, storage bus, memory controller bus, peripheral bus, or the like. The CPU 2902 may comprise any type of electronic data processor. The memory 2904 may comprise any type of system memory such as dynamic random access memory (DRAM), static random access memory (SRAM), synchronous DRAM (SDRAM), read-only memory (ROM), a combination thereof, or the like. In an embodiment, the memory may include ROM for use at boot-up, and DRAM for program and data storage for use while executing programs.

The mass storage device 2910 may comprise any type of storage device configured to store data, programs, and other information and to make the data, programs, and other information accessible via the bus 2912. The mass storage device 2910 may comprise one or more of a solid state drive, hard disk drive, a magnetic disk drive, an optical disk drive, or the like. In some embodiments, data, programs, or other information may be stored remotely, for example in the cloud. Computerized system 2900 may send or receive information to the remote storage in any suitable way, including via communications subsystem 2908 over a network or other data communication medium.

The I/O interface 2906 may provide interfaces for enabling wired and/or wireless communications between computerized system 2900 and one or more other devices or systems. For instance, I/O interface 2906 may be used to communicatively couple with sensors, such as cameras or video cameras. Furthermore, additional or fewer interfaces may be utilized. For example, one or more serial interfaces such as Universal Serial Bus (USB) (not shown) may be provided.

Computerized system 2900 may be used to configure, operate, control, monitor, sense, and/or adjust devices, systems, and/or methods according to the present disclosure.

A communications subsystem 2908 may be provided for one or both of transmitting and receiving signals over any form or medium of digital data communication, including a communication network. Examples of communication networks include a local area network (LAN), a wide area network (WAN), an inter-network such as the Internet, and peer-to-peer networks such as ad hoc peer-to-peer networks. Communications subsystem 2908 may include any component or collection of components for enabling communications over one or more wired and wireless interfaces. These interfaces may include but are not limited to USB, Ethernet (e.g. IEEE 802.3), high-definition multimedia interface (HDMI), Firewire™ (e.g. IEEE 1394), Thunderbolt™, WiFi™ (e.g. IEEE 802.11), WiMAX (e.g. IEEE 802.16), Bluetooth™, or Near-field communications (NFC), as well as GPRS, UMTS, LTE, LTE-A, and dedicated short range communication (DSRC). Communication subsystem 2908 may include one or more ports or other components (not shown) for one or more wired connections. Additionally or alternatively, communication subsystem 2908 may include one or more transmitters, receivers, and/or antenna elements (none of which are shown).

Computerized system 2900 of FIG. 29 is merely an example and is not meant to be limiting. Various embodiments may utilize some or all of the components shown or described. Some embodiments may use other components not shown or described but known to persons skilled in the art.

In the preceding description, for purposes of explanation, numerous details are set forth in order to provide a thorough understanding of the embodiments. However, it will be apparent to one skilled in the art that these specific details are not required. In other instances, well-known electrical structures and circuits are shown in block diagram form in order not to obscure the understanding. For example, specific details are not provided as to whether the embodiments described herein are implemented as a software routine, hardware circuit, firmware, or a combination thereof.

Embodiments of the disclosure can be represented as a computer program product stored in a machine-readable medium (also referred to as a computer-readable medium, a processor-readable medium, or a computer usable medium having a computer-readable program code embodied therein). The machine-readable medium can be any suitable tangible, non-transitory medium, including magnetic, optical, or electrical storage medium including a diskette, compact disk read only memory (CD-ROM), memory device (volatile or non-volatile), or similar storage mechanism. The machine-readable medium can contain various sets of instructions, code sequences, configuration information, or other data, which, when executed, cause a processor to perform steps in a method according to an embodiment of the disclosure. Those of ordinary skill in the art will appreciate that other instructions and operations necessary to implement the described implementations can also be stored on the machine-readable medium. The instructions stored on the machine-readable medium can be executed by a processor or other suitable processing device, and can interface with circuitry to perform the described tasks.

The above-described embodiments are intended to be examples only. Alterations, modifications and variations can be effected to the particular embodiments by those of skill in the art without departing from the scope, which is defined solely by the claims appended hereto.

What is claimed is:

1. An electronically tunable filter, comprising:
a signal generator for generating a transposition signal;
an input mixer in communication with the signal generator and configured to receive the transposition signal and a radio frequency (RF) input at a first frequency within an first RF band, the input mixer configured to output an up-converted RF input based on mixing the RF input with the transposition signal;
a filter in communication with the input mixer and configured to receive the up-converted RF input, the filter producing a filter output based on applying a filter characteristic to the up-converted RF input, wherein the filter is selected to have a passband for limiting operation of the signal generator to a second RF band non-overlapping with the first RF band, for transposing the RF input to within the passband of the filter, and
an output mixer in communication with the filter and the signal generator and configured to receive the filter output and the transposition signal, the output mixer configured to produce an RF output based on down-converting the filter output to the first frequency based on mixing with the transposition signal.

2. The electronically tunable filter of claim 1, wherein the input mixer and the output mixer comprise an image rejection mixer or a double balance mixer.

3. The electronically tunable filter of claim 1 or claim 2, wherein the filter is an RF filter comprising a cavity filter, a waveguide filter, a microstrip filter, and an integrated monolithic microwave integrate circuit filter.

4. The electronically tunable filter of any one of claims 1 to 3, wherein the filter comprises a bandpass filter having a filter bandwidth centered about a center frequency of the filter.

5. The electronically tunable filter of claim 4, wherein the bandpass filter comprises a cavity-based bandpass filter, wherein the center frequency is 44 GHz and the filter bandwidth is 2 GHz.

6. The electronically tunable filter of any one of claims 1 to 5, wherein the first RF band is about 1 GHz to about 20 GHz and the second RF band is about 24 GHz to about 43 GHz.

7. The electronically tunable filter of any one of claims 1 to 5, wherein a separation bandwidth between an upper limit of the first RF band and a lower limit of the second RF band is at least 1 GHz.

8. The electronically tunable filter of any one of claims 1 to 5, wherein a separation bandwidth between an upper limit of the first RF band and a lower limit of the second RF band is at least 500 MHz.

9. The electronically tunable filter of any one of claims 1 to 8, further comprising:
a first filter having a first low pass filter characteristic based on a first cutoff frequency, the first low pass filter being configured to receive the RF input and apply the first low pass filter characteristic, wherein the input mixer receives the RF input from an output of the first low pass filter.

10. The electronically tunable filter of claim 9, wherein the first cutoff frequency is 20 GHz.

11. The electronically tunable filter of any one of claims 1 to 10, further comprising:
a second filter having a second low pass filter characteristic based on a second cutoff frequency, the second low pass filter being in communication with the output mixer and configured to apply the second low pass filter characteristic to the RF output.

12. The electronically tunable filter of claim 11, wherein the second cutoff frequency is 20 GHz.

13. A cascaded filter, comprising:
a first electronically tunable filter according to any one of claims 1 to 12, connected in series with, a second electronically tunable filter according to any one of claims 1 to 12;
wherein the RF output of the first electronically tunable filter is provided as the RF input of the second electronically tunable filter.

14. The cascaded filter of claim 14, wherein the passband of the filter of the first electronically tunable filter is offset relative to the passband of the filter of the second electronically tunable filter.

15. The cascaded filter of claim 13 or 14, wherein an output of the cascaded filter is based on an overlap between the passband of the filter of the first electronically tunable filter and the passband of the filter of the second electronically tunable filter.

16. A notch filter, comprising:
a plurality of electronically tunable filters according to any one of claims 1 to 8 connected in parallel;
wherein a notch filter output comprises the RF output of each of the plurality of electronically tunable filters.

17. The notch filter of claim 16, wherein:
the plurality of electronically tunable filters comprises a first electronically tunable filter according to any one of claims 1 to 8, connected in parallel with, a second electronically tunable filter according to any one of claims 1 to 8;
wherein the notch filter output comprises the RF output of the first electronically tunable filter and the RF output of the second electronically tunable filter.

18. The notch filter of claim 17, further comprising:
a first low pass filter having a first low pass filter characteristic based on a first cutoff frequency, the first low pass filter being configured to receive the RF input and apply the first low pass filter characteristic, wherein the input mixer of each of the first and second electronically tunable filter receives the RF input from an output of the first low pass filter.

19. The notch filter of claim 18, wherein the first cutoff frequency is 20 GHz.

20. The notch filter of any one of claims 17 to 19, further comprising:
a second low pass filter having a second low pass filter characteristic based on a second cutoff frequency, the second low pass filter configured to apply the second low pass filter characteristic to the notch filter output;
wherein the notch filter output comprises an output of the second low pass filter.

21. The notch filter of claim 20, wherein the second cutoff frequency is 20 GHz.

22. The notch filter of any one of claims 17 to 21, wherein the passband of the filter of the first electronically tunable filter is offset relative to the passband of the filter of the second electronically tunable filter.

23. The notch filter of claim 22, further comprising a stopband between the passband of the first electronically tunable filter and the passband of the second electronically tunable filter, the stopband based on the relative offset between the passbands.

24. A nested electronically tunable filter (NETF), comprising:
an input transposition network configured to provide a first RF output comprising an RF input transposed up to a RF transposition frequency, the first RF output based on applying a first RF filter characteristic to an output of an up-conversion mixer configured to mix the RF input with a first transposition signal, wherein a passband of the first RF filter characteristic limits selection of the first transposition signal to a second RF band non-overlapping with a first RF band comprising the RF input;
an electronically tunable filter (ETF), comprising:
a signal generator for generating a second transposition signal;
an input mixer configured to provide an intermediate frequency (IF) output comprising the first RF output transposed down to an IF transposition frequency of an IF band, the IF output based on mixing the first RF output with the second transposition signal;
an IF filter in communication with the input mixer and configured to provide an IF filter output based on applying an IF filter characteristic to the IF output, and
an output mixer configured to provide a second RF output comprising the IF filter output transposed up to the RF transposition frequency, the second RF output based on mixing the IF filter output with the second transposition signal, and
an output transposition network configured to provide a third RF output comprising a second RF filter output transposed down to the first RF band, the third RF output based on an output of a down-conversion mixer configured to mix the second RF filter output with the first transposition signal, wherein the second RF filter output is based on applying a second RF filter characteristic to the second RF output.

25. The NETF of claim 24, wherein the up-conversion mixer, the input mixer, the output mixer, and the down-conversion mixer each comprise either a image rejection mixer or a double balance mixer.

26. The NETF 24 or claim 25, wherein the IF filter comprises a surface acoustic wave (SAW) filter, a multi-pole ceramic resonator filter, a microstrip filter, or a crystal filter.

27. The NETF of any one of claims 24 to 26, wherein the IF filter comprises a bandpass filter having a filter bandwidth centered about a center frequency of the filter.

28. The NETF of claim 27, wherein the bandpass filter comprises a SAW-based bandpass filter, wherein the center frequency is about 950 MHz and the filter bandwidth is about 150 MHz.

29. The NETF any one of claims 24 to 28, wherein the first RF band is about 1 GHz to about 20 GHz and the second RF band is about 21 GHz to about 40 GHz.

30. The NETF of any one of claims 24 to 28, wherein a separation bandwidth between an upper limit of the first RF band and a lower limit of the second RF band is at least 1 GHz.

31. The NETF of any one of claims 24 to 28, wherein a separation bandwidth between an upper limit of the first RF band and a lower limit of the second RF band is at least 500 MHz.

32. The NETF of any one of claims 24 to 31, further comprising:
a first filter having a first low pass filter characteristic based on a first cutoff frequency, the first low pass filter being configured to receive the RF input and apply the first low pass filter characteristic, wherein the up-conversion mixer receives the RF input from an output of the first low pass filter.

33. The NETF of claim 32, wherein the first cutoff frequency is 20 GHz.

34. The NETF of any one of claims 24 to 32, further comprising:
a second filter having a second low pass filter characteristic based on a second cutoff frequency, the second low pass filter being in communication with the down-conversion mixer and configured to apply the second low pass filter characteristic to the third RF output.

35. The NETF of claim 34, wherein the second cutoff frequency is 20 GHz.

36. A nested electronically tunable filter (NETF), comprising:
an input transposition network configured to provide a first RF output comprising an RF input transposed up to a RF transposition frequency, the first RF output based on applying a first RF filter characteristic to an output of an up-conversion mixer configured to mix the RF input with a first transposition signal, wherein a passband of the first RF filter characteristic limits selection of the first transposition signal to a second RF band non-overlapping with a first RF band comprising the RF input;
a first electronically tunable filter connected in series with a second electronically tunable filter, each of the first ETF and the second ETF comprising:
a signal generator for generating a second transposition signal;
an input mixer configured to provide an intermediate frequency (IF) output comprising the first RF output transposed down to an IF transposition frequency of an IF band, the IF output based on mixing the first RF output with the second transposition signal;
an IF filter in communication with the input mixer and configured to provide an IF filter output based on applying an IF filter characteristic to the IF output, and
an output mixer configured to provide a second RF output comprising the IF filter output transposed up to the RF transposition frequency, the second RF output based on mixing the IF filter output with the second transposition signal;
wherein the first RF input of the second ETF comprises the second RF output of the first ETF, and
an output transposition network configured to provide a third RF output comprising a second RF filter output transposed down to the first RF band, the third RF output based on an output of a down-conversion mixer configured to mix the second RF filter output with the first transposition signal, wherein the second RF filter output is based on applying a second RF filter characteristic to the second RF output.

37. The NETF of claim 36, wherein a passband of the IF filter characteristic of the first ETF is offset relative to a passband of the IF filter characteristic of the second ETF.

38. The NETF filter of claim 37, wherein an output of the NETF is based on an overlap between the passband of the IF filter of the first ETF and the passband of the IF filter of the second ETF.

39. A method for implementing at wideband electronically tunable filter, comprising:
receiving an RF input at a first frequency within a first RF band;
up-converting the RF input based on mixing the RF input with a transposition signal from a second RF band non-overlapping with the first RF band;
generating an RF filter output based on applying an RF filter characteristic to the up-converted RF input;
down-converting the RF filter output based on mixing the RF filter output with the transposition signal, and
outputting an RF output based on the down-converted RF filter output.

40. The method of claim 39, wherein the up-converting and down-converting based on mixing comprises use of either an image rejection mixer or a double balance mixer.

41. The method of claim 39 or claim 40, wherein the generating the RF filter output comprises use of an RF filter selected from the group consisting of a cavity filter, a waveguide filter, a microstrip filter, and an integrated monolithic microwave integrate circuit filter.

42. The method of any one of claims 39 to 41, wherein the RF filter characteristic comprises a bandpass filter characteristic having a center frequency and a filter bandwidth.

43. The method of claim 42, wherein the center frequency is about 44 GHz and the filter bandwidth is about 2 GHz.

44. The method of any one of claims 39 to 43, wherein the first RF is about 1 GHz to about 20 GHz and the second RF band is about 24 GHz to about 43 GHz.

45. The method of any one of claims 39 to 43, wherein a separation bandwidth between an upper limit of the first RF band and a lower limit of the second RF band is at least 1 GHz.

46. The method of any one of claims 39 to 43, wherein a separation bandwidth between an upper limit of the first RF band and a lower limit of the second RF band is at least 500 MHz.

47. The method of any one of claims 39 to 46, further comprising:
applying a first low pass filter characteristic to the RF input, the first low pass filter characteristic having a first cutoff frequency.

48. The method of claim 47, wherein the first cutoff frequency is 20 GHz.

49. The method of any one of claims 39 to 48, further comprising:
applying a second low pass filter characteristic to the RF output, the second low pass filter characteristic having a second cutoff frequency.

50. The method of claim 49, wherein the second cutoff frequency is 20 GHz.

51. A method for implementing a cascaded filter, comprising:
implementing a first electronically tunable filter according to the method of any one of claims 39-50 in series with, a second electronically tunable filter according to the method of any one of claims 39-50;
wherein the RF output of the first electronically tunable filter is provided as the RF input of the second electronically tunable filter.

52. The method of claim 51, further comprising:
applying the RF filter characteristic of the first electronically tunable filter at a first RF center frequency, and
applying the RF filter characteristic of the second electronically tunable filter at a second RF center frequency;
wherein the first RF center frequency and the second RF center frequency are relatively offset.

53. The method of claim 51 or claim 52, wherein an output of the cascaded filter is based on an overlapping passband between the RF filter characteristic of the first electronically tunable filter and the RF filter characteristic of the second electronically tunable filter.

54. A method for implementing a notch filter, comprising:
implementing a plurality of electronically tunable filters according to the method of any one of claims 39-46, each of the plurality of the plurality of electronically tunable filters being connected in parallel, and
outputting a notch filter output comprising the RF output of each of the plurality of electronically tunable filters.

55. A method for implementing a notch filter, comprising:
implementing a first electronically tunable filter according to the method of any one of claims 39 to 46 in parallel with a second electronically tunable filter according to the method of any one of claims 39 to 46;
outputting a notch filter output comprising the RF output of the first electronically tunable filter and the RF output of the second electronically tunable filter.

56. The method according to claim 55, further comprising:
applying a first low pass filter characteristic to the RF input, the first low pass filter characteristic having a first cutoff frequency.

57. The method according to claim 56, wherein the first cutoff frequency is 20 GHz.

58. The method according to any one of claims 55 to 57, further comprising:
applying a second low pass filter characteristic to the notch filter output, the second low pass filter characteristic having a second cutoff frequency.

59. The method according to claim 58, wherein the second cutoff frequency is 20 GHz.

60. The method according to any one of claims 55 to 59, further comprising:
applying the RF filter characteristic of the first electronically tunable filter at a first RF center frequency, and
applying the RF filter characteristic of the second electronically tunable filter at a second RF center frequency;
wherein the first RF center frequency and the second RF center frequency are relatively offset.

61. The method according to claim 60, further comprising:
controlling a bandwidth of a stopband based on adjusting a relative offset between the first RF center frequency and the second RF center frequency.

62. A method for implementing a nested electronically tunable filter at an intermediate frequency (IF), comprising:
receiving an RF input at a first frequency within an first RF band;
up-converting the RF input based on mixing the RF input with a transposition signal from a second RF band non-overlapping with the first RF band;
generating an RF filter output based on applying an RF filter characteristic to the up-converted RF input;
down-converting the RF filter output to an IF band based on mixing the RF filter output with a second transposition signal;
generating an IF filter output based on applying an IF filter characteristic to the down-converted RF filter output;
up-converting the IF filter output based on mixing the RF filter output with the second transposition signal;
generating a second RF filter output based on applying a second RF filter characteristic to the up-converted IF filter output;
down-converting the second RF filter output based on mixing the second RF filter output with the transposition signal, and
outputting an RF output based on the down-converted RF filter output.

63. The method of claim 62, wherein all steps of mixing comprise use of either a image rejection mixer or a double balance mixer.

64. The method of claim 62 or claim 63, wherein the IF filter comprises a surface acoustic wave (SAW) filter, a multi-pole ceramic resonator filter, a microstrip filter, or a crystal filter.

65. The method of any one of claims 62 to 63, wherein the IF filter comprises a bandpass filter having a filter bandwidth centered about a center frequency.

66. The method of claim 65, wherein the bandpass filter comprises a SAW-based bandpass filter, wherein the filter bandwidth is about 150 MHz and the center frequency is about 950 MHz.

67. The method of any one of claims 62 to 66, wherein the first RF band comprises 1 GHz to 20 GHz and the second RF band comprises 21 GHz to 40 GHz.

68. The method of any one of claims 62 to 66, wherein a separation bandwidth between an upper limit of the first RF band and a lower limit of the second RF band is at least 1 GHz.

69. The method of any one of claims 62 to 66, wherein a separation bandwidth between an upper limit of the first RF band and a lower limit of the second RF band is at least 500 MHz.

70. The method of any one of claims 62 to 69, further comprising:
applying a first low pass filter characteristic to the RF input, the first low pass filter characteristic having a first cutoff frequency.

71. The method of claim 70, wherein the first cutoff frequency is 20 GHz.

72. The method of any one of claims 62 to 71, further comprising:
applying a second low pass filter characteristic to the RF output, the second low pass filter characteristic having a second cutoff frequency.

73. The method of claim 72, wherein the second cutoff frequency is 20 GHz.

74. A method for implementing serially cascaded electronically tunable filters, nested at an intermediate frequency (IF), comprising:
receiving an RF input at a first frequency within an first RF band;
up-converting the RF input based on mixing the RF input with a transposition signal from a second RF band non-overlapping with the first RF band;
generating an RF filter output based on applying an RF filter characteristic to the up-converted RF input;
down-converting the RF filter output to an IF band based on mixing the RF filter output with a second transposition signal;
generating an IF filter output based on applying an IF filter characteristic to the down-converted RF filter output;
up-converting the IF filter output based on mixing the RF filter output with the second transposition signal;
down-converting the up-converted IF filter output based on mixing the up-converted IF filter output with a third transposition signal;
generating a second IF filter output based on applying a second IF filter characteristic to the down-converted IF filter output;
up-converting the second IF filter output based on mixing the second IF filter output with the third transposition signal;
generating a second RF filter output based on applying a second RF filter characteristic to the up-converted second IF filter output;
down-converting the second RF filter output based on mixing the second RF filter output with the transposition signal, and
outputting an RF output based on the down-converted RF filter output.

75. The method of claim 74, further comprising:
applying the IF filter characteristic at a first IF center frequency, and
applying the second IF filter characteristic at a second RF center frequency;
wherein the first IF center frequency and the second IF center frequency are relatively offset.

76. The method of claim 74 or claim 75, wherein the RF output is based on an overlapping passband between the IF filter characteristic and the second IF filter characteristic.

77. A computer-readable medium having instructions stored thereon that when executed by a processor perform a method for implementing a filter in accordance with any one of claims 39 to 76.
